(19) United States
(12) Patent Application Publication
(10) Pub. No.: US 2026/0290409 A1
(43) Pub. Date: Sep. 24, 2026

(54) MICROELECTRONIC DEVICES, AND RELATED METHODS, MEMORY DEVICES AND ELECTRONIC SYSTEMS

(71) Applicant: Micron Technology, Inc., Boise, ID (US)

(72) Inventors: Giovanni Mazzone, Villasanta (IT); Anna Maria Conti, Milano (IT); Lorenzo Pedrazzetti, Soncino (IT); Lifang Xu, Boise, ID (US); David H. Wells, Boise, ID (US); Harsh Narendrakumar Jain, Boise, ID (US); Vladimir Samara, Boise, ID (US)

(21) Appl. No.: 19/545,455

(22) Filed: Feb. 20, 2026

Related U.S. Application Data
(60) Provisional application No. 63/774,321, filed on Mar. 19, 2025.

(51) Int. Cl. G11C 5/06; G11C 16/04; H10B 41/10; H10B 41/27; H10B 41/35; H10B 43/10; H10B 43/27; H10B 43/35

(52) U.S. Cl. CPC G11C 5/063; G11C 16/0483; H10B 41/10; H10B 41/27; H10B 41/35; H10B 43/10; H10B 43/27; H10B 43/35

(57) ABSTRACT

A microelectronic device includes a stack structure, a memory array region, and an extension region horizontally neighboring the memory array region. The stack structure comprises levels of conductive material vertically alternating with levels of insulative material. The extension region includes an array extension region abutting the array region, and a select gate drain (SGD) contact region at least partially horizontally overlapping the array extension region. The SGD contact region comprises SGD contact structures extending vertically to one of the levels of conductive material within an upper section of the stack structure. The device includes a word line (WL) contact region horizontally neighboring the SGD contact region of the extension region. The WL contact region comprises WL contact structures individually in contact with another one of the levels of conductive material within a lower section of the stack structure and extending vertically through the entire vertical height of the stack structure.

### CROSS-REFERENCE TO RELATED APPLICATIONS

This application claims the benefit under 35 U.S.C. § 119(e) of U.S. Provisional Patent Application Ser. No. 63/774,321, filed Mar. 19, 2025, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices, such as Flash memory devices. A conventional Flash memory device generally includes a memory array having charge storage devices (e.g., memory cells, such as non-volatile memory cells) arranged in rows and columns. In a NAND architecture type of flash memory, memory cells arranged in a column are coupled in series, and a first memory cell of the column is coupled to a data line (e.g., a bit line). In a “three-dimensional NAND” memory device (which may also be referred to herein as a “3D NAND” memory device), not only are the memory cells arranged in row and column fashion in a horizontal array, but tiers of the horizontal arrays are stacked over one another (e.g., as vertical strings of memory cells) to provide a “three-dimensional array” of the memory cells. The stack structure of tiers vertically alternate conductive materials with insulative (e.g., dielectric) materials. The conductive materials function as control gates for access lines (e.g., word lines) of the memory cells. Vertical structures (e.g., pillars comprising channel structures and tunneling structures) extend along the vertical string of memory cells. A drain end of a string is adjacent one of the top and bottom of the vertical structure, while a source end of the string is adjacent the other of the top and the bottom of the pillar. The drain end is operably connected to a bit line, while the source end is operably connected to a source structure (e.g., a source plate, a source line). A 3D NAND memory device also includes electrical connections between the access lines and other conductive structures of the device so that the memory cells of the vertical strings can be selected for writing, reading, and erasing operations.

A continued goal in the microelectronic device fabrication industry is to reduce the footprint of the features of microelectronic devices so as to maximize the number of devices, and functional features thereof, in a given structural area. However, as device and feature sizes are reduced (e.g., scaled to smaller sizes) to accommodate a greater density of features, and as features are fabricated at the base of openings with higher aspect ratios, precise and accurate fabrication of structure features may be more challenging and may lead to fabrication errors. Accordingly, designing and fabricating 3D NAND memory devices continues to present challenges.

### BRIEF DESCRIPTION OF THE DRAWINGS

FIG. 1 is a simplified, partial top-view of the microelectronic device structure 100 in accordance with some embodiments of the disclosure;

FIGS. 2 through 9B are simplified, partial vertical cross-sectional views (FIGS. 2-6, 7B, 8B and 9) and simplified, partial top-down views (FIGS. 7A, 8A and 9A) illustrating different processing stages of a method of forming a microelectronic device, in accordance with embodiments of the disclosure;

FIGS. 10 through 14 are simplified, partial vertical cross-sectional views (FIGS. 10-12 and 14) and a simplified, partial top-down view (FIG. 13) illustrating different processing stages of a method of forming a microelectronic device, in accordance with embodiments of the disclosure;

FIGS. 15 through 17 are simplified, partial vertical cross-sectional views illustrating different processing stages of a method of forming a microelectronic device, in accordance with embodiments of the disclosure;

FIGS. 18 through 25B are simplified, partial vertical cross-sectional views (FIGS. 18, 19, 21, 22B, 23B, 24 and 25B) and simplified, partial top-down views (FIGS. 20, 22A, 23A and 25B) illustrating different processing stages of a method of forming a microelectronic device, in accordance with embodiments of the disclosure; and

FIG. 26 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those processing acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “downward,” “bottom,” “above,” “upper,” “upward,” “top,” “front,” “rear,” “left,” “right,” “side,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, any ordinal terms, such as “first,” “second,” etc., is used for clarity and convenience in understanding the disclosure and accompanying drawings or to distinguish one claimed construct from another, and do not connote or depend on any specific sequence, preference, time, uniqueness, or order, except where the context clearly indicates otherwise.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, the term “configured” refers to a size, shape, material composition, orientation, and arrangement of one or more of at least one structure and at least one apparatus facilitating operation of one or more of the structure and the apparatus in a predetermined way.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni-and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “amorphous,” when referring to a material, means and refers to a material having a substantially noncrystalline structure.

As used herein, the term “high-K dielectric material” means and includes a dielectric material having a dielectric constant greater than the dielectric constant of silicon dioxide (SiO₂). By way of example only, the high-K dielectric material include one or more of aluminum oxide, gadolinium oxide, hafnium oxide, niobium oxide, tantalum oxide, titanium oxide, zirconium oxide, and hafnium silicate.

As used herein, the term “sacrificial,” when used in reference to a material or structure, means and includes a material, structure, or a portion of a material or structure that is formed during a fabrication process but that is at least partially removed (e.g., substantially removed) prior to completion of the fabrication process.

As used herein, the term “selectively etchable” means and includes a material that exhibits a greater etch rate responsive to exposure to a given etch chemistry relative to another material exposed to the same etch chemistry. For example, the material may exhibit an etch rate that is at least about three times (3×) greater than the etch rate of another material, such as about five times (5×) greater than the etch rate of another material, such as an etch rate of about ten times (10×) greater, about twenty times (20×) greater, or about forty times (40×) greater than the etch rate of the another material. Etch chemistries and etch conditions for selectively etching a desired material may be selected by a person of ordinary skill in the art.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

A three-dimensional (3D) memory device (e.g., 3D NAND memory device) may include a stack structure including levels of conductive material vertically alternating with levels of insulative material. The 3D memory device may have an array region, an array extension region horizontally (e.g., in the X-direction) abutting the array region, and a contact region horizontally neighboring the array extension region. The array region may have arrays of memory cell pillars (vertical strings of memory cells). The array extension region may have an arrangement of supporting pillar structures to provide structural support for the memory pillars in the array region during the fabrication process (e.g., during replacement gate processing acts described herein). The contact region may have a section of drain-side select gate contacts (referred to herein as “SGD contact region”), and a section of word line contacts (referred to herein as “WL contact region”) horizontally neighboring the SGD contact region. The conductive contacts in the SGD contact region and the WL contact region electrically connect the memory cells in the array region to other conductive features (e.g., a bit line and a source structure, respectively) of the memory device, so that the memory cells of the vertical strings can be selected for writing, reading, and erasing operations. As vertical memory array technology has advanced, the number of levels of conductive material in the stack structure continues to increase. To allow sufficient electrical communication between the memory cells in the array region and other conductive features of the memory device, the contact regions (including the SGD contact region and the WL contact region) of many conventional 3D memory device have continued to expand and require more footprint. Furthermore, for many conventional 3D memory devices, a continuingly increasing number of supporting pillar structures in the array extension region has been required to prevent the collapsing or bending of the stack structure during fabrication of the memory device (e.g., during a replacement gate process), and thereby demanding a larger footprint for the array extension region.

In a microelectronic device (e.g., memory devices such as 3D NAND memory device) according to embodiments of the disclosure, a SGD contact region (including SGD contact structures) thereof is at least partially horizontally overlapped by an array extension region (including supporting pillar structures) thereof, thereby reducing an overall required footprint of microelectronic device and/or increasing the memory density of the microelectronic device. In some embodiments, at least about 10 percent (%) (e.g., at least about 20%, at least 30%, at least about 40%, at least about 50%, at least about 60%, at least about 70%, at least about 80%, or at least about 90%) of the SGD contact region of a microelectronic device of the disclosure is horizontally overlapped with the array extension region of the microelectronic device. In some embodiments, the SGD contact region of the microelectronic device of the disclosure is substantially horizontally overlapped (e.g., about 100% overlapped) with the array extension region of the microelectronic device.

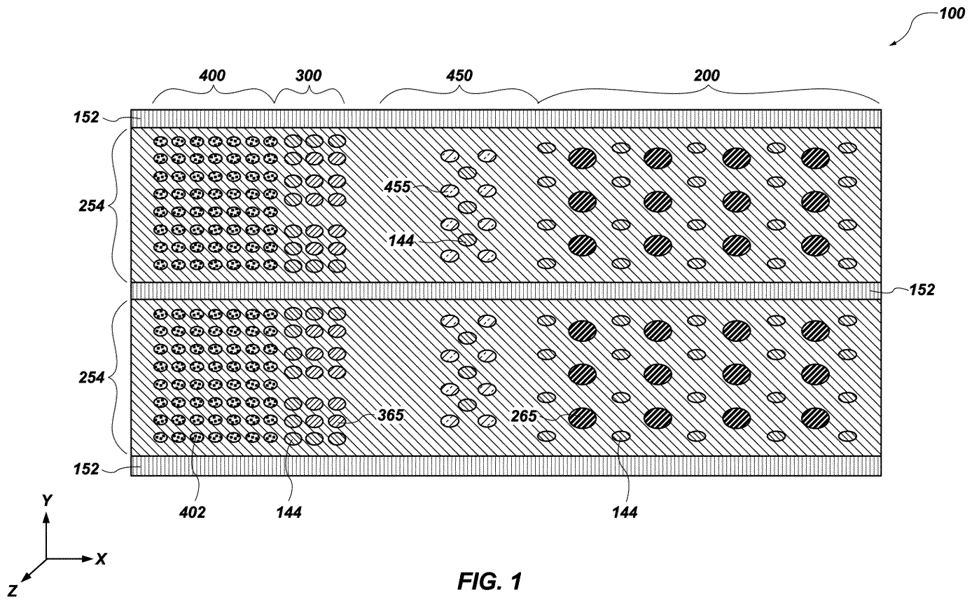

FIG. 1 is a simplified, partial top-down view of a microelectronic device structure 100 for a microelectronic device (e.g., a memory device, such as a 3D NAND Flash memory device), in accordance with some embodiments of the disclosure. The microelectronic device structure 100 includes an array region 400, a region 300 horizontally (e.g., in an X-direction) neighboring the array region 400, a WL contact region 200 horizontally neighboring the region 300, and, optionally, a transition region 450 horizontally between the WL contact region 200 and the extension region 300. The array region 400 includes an array of memory cell pillars 402 defining vertically extending strings of memory cells. The extension region 300 includes an array extension region horizontally abutting the array region 400, and an SGD contact region horizontally adjacent to the array extension region and at least partially overlapped by the array extension region. The extension region 300 has additional conductive contacts 365 therein. Since the array extension region of the extension region 300 is at least partially horizontally overlapped with the SGD contact region of the extension region 300, the array extension region and the SGD contact region will be collectively referred to herein as “extension/SGD contact region 300.” The WL contact region 200 has conductive contacts 265 therein. The microelectronic device structure 100 may also include support pillars 144 within one or more of the array region 400, the WL contact region 200, and the optional transition region 450 to provide structural support to the microelectronic device structure 100 during fabrication processing. In addition, the microelectronic device structure 100 of FIG. 1 includes deep contact structures 455 including conductive material within the transition region 450. The microelectronic device structure 100 is segmented into blocks 254 by first dielectric-filled slot structures 152 respectively at least partially formed of and including dielectric material. Features of the array region 400 of the microelectronic device structure 100 may be formed substantially simultaneous with or sequentially with formation of corresponding features of the WL contact region 200 and/or the extension/SGD contact region 300.

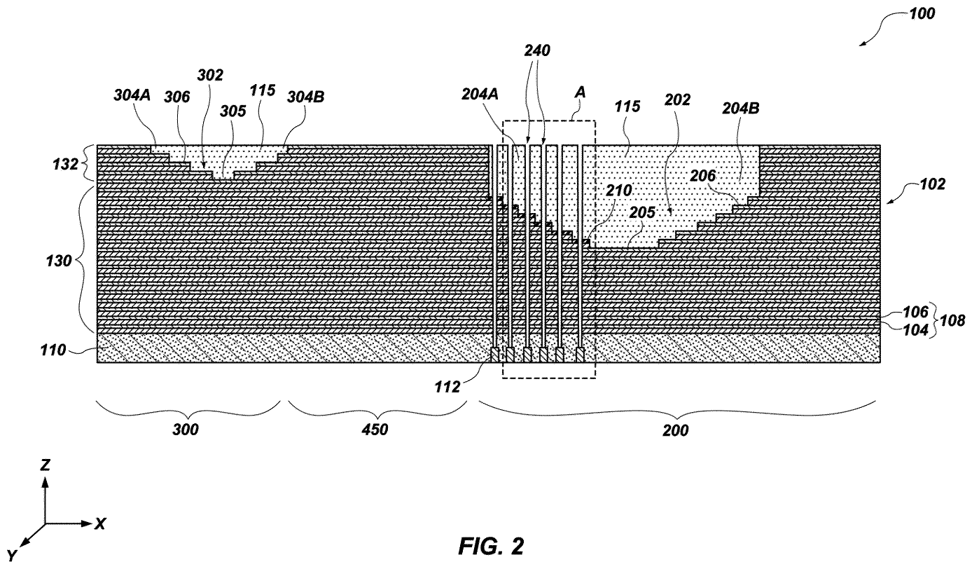

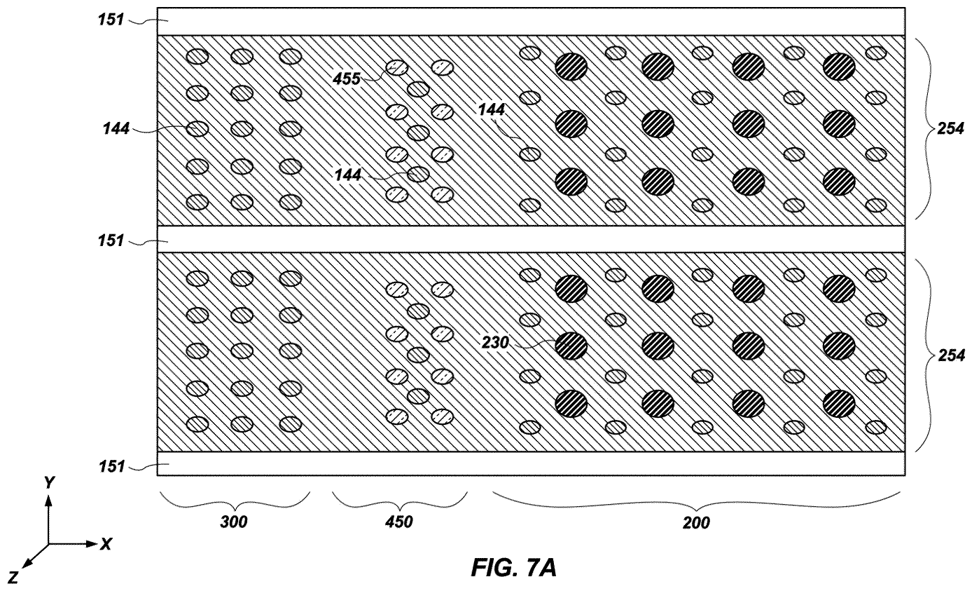

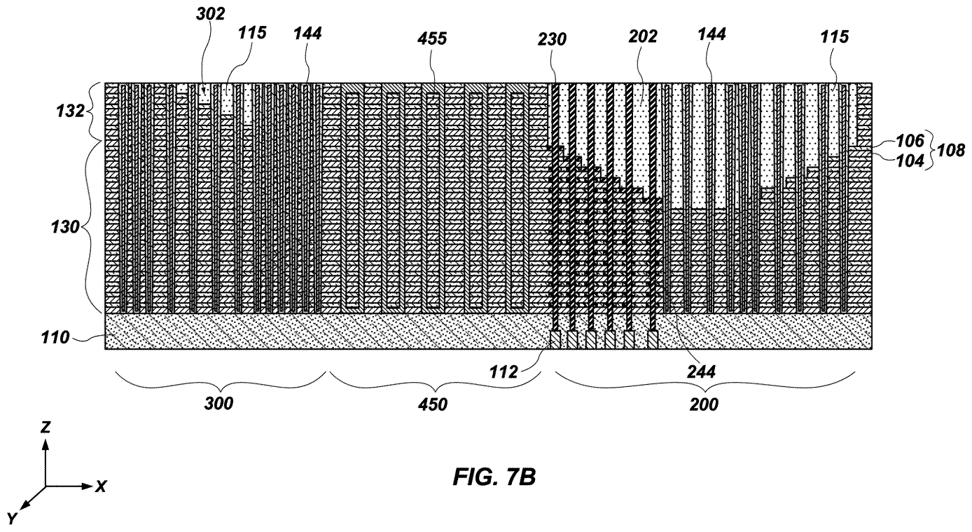

FIGS. 2 through 9B are simplified, partial vertical cross-sectional views (FIGS. 2-6, 7B, 8B, and 9) and simplified, partial top-down views (FIGS. 7A, 8A, and 9A) illustrating different processing stages of a method of forming a microelectronic device (e.g., a memory device, such as a 3D NAND Flash memory device), in accordance with some embodiments of the disclosure. With the description provided below, it will be readily apparent to one of ordinary skill in the art that the methods and structures described herein with reference to FIGS. 2 through 9B may be used in the formation and configuration of various devices and electronic systems. In other words, the methods of the disclosure may be used whenever it is desired to form a microelectronic device.

Referring to FIG. 2, a method for forming a microelectronic device may include forming a preliminary stack structure 102 over a base structure 110 comprising conductive structures 112 (e.g., conductive routing structures, conductive line structures). The preliminary stack structure 102 may be formed to include a vertically alternating (e.g., in the Z-direction) sequence of insulative material 104 and sacrificial material 106 arranged in tiers 108. Each of the tiers 108 of the preliminary stack structure 102 may individually include the sacrificial material 106 vertically neighboring (e.g., directly vertically adjacent) the insulative material 104. The preliminary stack structure 102 may include a lower section 130 and an upper section 132 overlying the lower section 130. The upper section 132 of the preliminary stack structure 102 may include a group of the tiers 108 that is relatively more distal from the base structure 110. The lower section 130 of the preliminary stack structure 102 may include an additional group of the tiers 108 that is relatively more proximate to the base structure 110.

The insulative material 104 of each of the tiers 108 of the preliminary stack structure 102 may be formed of and include at least one dielectric material, such one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 104 of each of the tiers 108 of the preliminary stack structure 102 is formed of and includes a dielectric oxide material, such as SiOₓ (e.g., SiO₂). The insulative material 104 of each of the tiers 108 may be substantially homogeneous, or the insulative material 104 of one or more (e.g., each) of the tiers 108 may be heterogeneous.

The sacrificial material 106 of each of the tiers 108 of the preliminary stack structure 102 may be formed of and include at least one material (e.g., at least one insulative material) that may be selectively removed relative to the insulative material 104. The sacrificial material 106 may be selectively etchable relative to the insulative material 104 during common (e.g., collective, mutual) exposure to a first etchant; and the insulative material 104 may be selectively etchable to the sacrificial material 106 during common exposure to a second, different etchant. By way of non-limiting example, depending on the material composition of the insulative material 104, the sacrificial material 106 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductor material (e.g., polycrystalline silicon). In some embodiments, the sacrificial material 106 of each of the tiers 108 of the preliminary stack structure 102 is formed of and includes a dielectric nitride material, such as SiN_{y} (e.g., Si₃N₄). The sacrificial material 106 may, for example, be selectively etchable relative to the insulative material 104 during common exposure to a wet etchant comprising phosphoric acid (H₃PO₄).

The lower section 130 and the upper section 132 of the preliminary stack structure 102 may respectively be formed to include any desired quantity of the tiers 108. By way of non-limiting example, the lower section 130 of the preliminary stack structure 102 and the upper section 132 of the preliminary stack structure 102 may together be formed to include greater than or equal to sixteen (16) of the tiers 108, such as greater than or equal to thirty-two (32) of the tiers 108, greater than or equal to sixty-four (64) of the tiers 108, greater than or equal to one hundred and twenty-eight (128) of the tiers 108, or greater than or equal to two hundred and fifty-six (256) of the tiers 108. In some embodiments, the lower section 130 of the preliminary stack structure 102 includes a greater quantity of the tiers 108 than the upper section 132 of the preliminary stack structure 102. In some embodiments, the upper section 132 of the preliminary stack structure 102 is formed to include greater than or equal to four (4) of the tiers 108, such as greater than or equal to six (6) of the tiers 108, greater than or equal to eight (8) of the tiers 108, or greater than or equal to sixteen (16) of the tiers 108.

As shown in FIG. 2, the preliminary stack structure 102 may include the WL contact region 200, the extension/SGD contact region 300 horizontally adjacent to the WL contact region 200, and the optional transition region 450 horizontally between the WL contact region 200 and the extension/SGD contact region 300.

The WL contact region 200 may be formed to include at least one stadium structure (also referred to herein as “WL stadium structure”) 202. The WL stadium structure 202 may be formed within the horizonal area of the WL contact region 200 and vertically within the lower section 130 of the preliminary stack structure 102. The lower section 130 of the preliminary stack structure 102 may include any desired quantity and distribution of WL stadium structures 202. The WL contact region 200 of the preliminary stack structure 102 may include rows of the WL stadium structures 202 extending in parallel in a X-direction, and columns of the WL stadium structures 202 extending in a Y-direction orthogonal to the X-direction. The rows of the WL stadium structures 202 may individually include some of the WL stadium structures 202 at least partially (e.g., substantially) aligned with one another in the Y-direction. The columns of the of the WL stadium structures 202 may individually include other of the WL stadium structures 202 at least partially (e.g., substantially) aligned with one another in the X-direction. Different rows of the WL stadium structures 202 may be positioned within different horizontal areas of the preliminary stack structure 102 to be formed into different blocks of a stack structure to be formed from the preliminary stack structure 102, as described in further detail below. Furthermore, at least some (e.g., each) of the WL stadium structures 202 within an individual row of the WL stadium structures 202 may be positioned at different vertical elevations in the Z-direction than one another.

Each of the WL stadium structures 202 may be formed to include opposing staircases 204 (represented in FIG. 2 as a forward staircase 204A and a reverse staircase 204B) and a central region 205 horizontally interposed between (e.g., in the X-direction) the opposing staircases. As shown in FIG. 2, the opposing staircases 204 of an individual WL stadium structure 202 may be positioned at substantially the same vertical position as one another, and may exhibit topographic profiles substantially mirroring one another. However, one or more of the WL stadium structures 202 may individually exhibit a different configuration than that depicted in FIG. 2. As a non-limiting example, at least one WL stadium structures 202 may be modified to include a forward staircase 204A but not a reverse staircase 204B, or at least one WL stadium structures 202 may be modified to include a reverse staircase 204B but not a forward staircase 204A. As another non-limiting example, at least one WL stadium structure 202 may be modified such that the forward staircase 204A thereof is at least partially (e.g., completely) vertically offset (e.g., in the Z-direction) from the reverse staircase 204B thereof.

The opposing staircases 204 of the WL stadium structures 202 respectively include steps 206 defined by edges (e.g., horizontal ends) of at least some of the tiers 108 of the lower section 130 of the preliminary stack structure 102. An individual step 206 may include a tread defined by a portion of an upper surface of a respective one of the tiers 108 of the lower section 130, and may also include a riser defined by a side surface the respective one of the tiers 108 of the lower section 130. Each of the opposing staircases 204 may individually include a desired quantity of steps 206. Each of the opposing staircases 204 of an individual WL stadium structure 202 may include substantially the same quantity of steps 206 as one another, or one of the opposing staircases 204 of the WL stadium structure 202 may include a different quantity of steps 206 than the other of the opposing staircases 204 of the WL stadium structure 202. For clarity and ease of understanding the description, FIG. 2 illustrates only a particular quantity of steps 206 in each of the opposing staircases 204 of the WL stadium structure 202. However, it will be understood that the opposing staircases 204 of the WL stadium structure 202 may individually include a greater or lesser quantity of steps 206 than those illustrated. For example, the opposing staircases 204 of a respective WL stadium structure 202 may individually include greater or equal to eight (8) of the steps 206, greater than or equal to sixteen (16) of the steps 206, greater than or equal to thirty-two (32) of the steps 206, greater than or equal to sixty-four (64) of the steps 206, greater than or equal to one-hundred and twenty-eight (128) of the steps 206, or greater than or equal to two-hundred and fifty-six (256) of the steps 206.

Still referring to FIG. 2, implanted regions 210 may be formed within the portions of the sacrificial material 106 of some of the tiers 108 at selected steps 206 of the forward staircase 204A of the WL stadium structure 202. One or more processing acts may be performed to selectively form the implanted regions 210 within the portions of the sacrificial material 106 of some of the tiers 108 at the selected steps 206 of the forward staircase 204A of the WL stadium structure 202. For example, other areas of the microelectronic device structure 100 (e.g., the WL contact region 200, the transition region 450, as well as the reverse staircase 204B and the central region 205 of the WL stadium structure 202) may be substantially protected (e.g., using a mask) from the processing acts, while portions of the sacrificial material 106 of some of the tiers 108 at the selected steps 206 of the forward staircase 204A of the WL stadium structure 202 are exposed to the processing acts. The exposed portions of the sacrificial material 106 of some of the tiers 108 at the selected steps 206 may be subjected to (e.g., exposed to) one or more treatment acts that change a material composition of the exposed portions of the sacrificial material 106. For example, the exposed portions of the sacrificial material 106 of some of the tiers 108 may be implanted with boron, carbon, oxygen, gallium, or a combination thereof. The treatment acts may change a material composition of the exposed portions of the sacrificial material 106 compared to a material composition of the unexposed portions of the sacrificial material 106. The implanted regions 210 may be formed within the exposed portions of the sacrificial material 106 of some of the tiers 108, without being formed within the sacrificial material 106 of some others of the tiers 108 vertically underlying the exposed portions of the sacrificial material 106 of some of the tiers 108.

For clarity and ease of understanding of the drawings and related description, FIG. 2 is shown as having the implanted regions 210 at the steps 206 of the forward staircase 204A of the WL stadium structure 202. However, the disclosure is not limited. The implanted regions 210 may be formed at the steps 206 of the reverse staircase 204B of the WL stadium structure 202, or at the steps 206 of both the forward staircase 204A and the reverse staircase 204B of the WL stadium structure 202. The implanted regions 210 may also be formed at the central region 205 of the WL stadium structure 202.

The material of the implanted regions 210 of the exposed sacrificial material 106 may, for example, be formed of and include one or more of carbon-containing material (e.g., carbon-doped silicon nitride, silicon carbon nitride (SiCN)), boron-containing material (e.g., boron-doped silicon nitride), or gallium-containing material. By way of non-limiting example, the material of the implanted regions 210 may be formed of and include one or more of boron nitride (BN_{y}), gallium nitride (GaN), oxynitride material (e.g., SiOₓN_{y}), and carboxynitride material (e.g., SiOₓC_{z}N_{y}). In some embodiments, the implanted regions 210 comprise boron-doped nitride material and/or carbon-doped nitride material.

The implant conditions and the dopant concentration may be tailored to achieve desired etch selectivity of the insulative material 104 and other materials relative to the implanted regions 210. For example, the implant conditions may be formulated to achieve a desired etch selectivity of the implanted regions 210, such that the material of the implanted regions 210 is selectively removable during material removal processes used to remove the sacrificial material 106, including the unexposed portions of the sacrificial material 106 of the preliminary stack structure 102. Accordingly, the sacrificial material 106 and the implanted regions 210 may be subsequently removed in a single processing act, responsive to the implant conditions used to form the implanted regions 210. In additional embodiments, the implanted regions 210 exhibit etch electivity relative to the sacrificial material 106, such that the sacrificial material 106 and the implanted regions 210 are subsequently removed in multiple (e.g., two or more) processing acts.

Referring to the extension/SGD contact region 300 of the microelectronic device structure 100 of FIG. 2, the extension/SGD contact region 300 may be formed to include at least one additional stadium structure (also referred to herein as “SGD stadium structure”) 302. The SGD stadium structure 302 may be formed within the horizonal area of the extension/SGD contact region 300 and vertically within the upper section 132 of the preliminary stack structure 102. The upper section 132 of the preliminary stack structure 102 may include any desired quantity and distribution of SGD stadium structures 302.

Each of the SGD stadium structures 302 may be formed to include opposing staircases 304 (represented in FIG. 2 as a forward staircase 304A and a reverse staircase 304B) and a central area 305 horizontally interposed between (e.g., in the X-direction) the opposing staircases 304. As shown in FIG. 2, the opposing staircases 304 of an individual SGD stadium structure 302 may be positioned at substantially the same vertical position as one another, and may exhibit topographic profiles substantially mirroring one another. However, one or more of the SGD stadium structures 302 may individually exhibit a different configuration than that depicted in FIG. 2. As a non-limiting example, an individual SGD stadium structure 302 may be modified to include a forward staircase 304A but not a reverse staircase 304B, or an individual SGD stadium structure 302 may be modified to include a reverse staircase 304B but not a forward staircase 304A.

The opposing staircases 304 of an individual SGD stadium structure 302 respectively include steps 306 defined by edges (e.g., horizontal ends) of at least some of the tiers 108 of the upper section 132 of the preliminary stack structure 102. An individual step 306 may include a tread defined by a portion of an upper surface of a respective one of the tiers 108 of the upper section 132, and may also include a riser defined by a side surface the respective one of the tiers 108 of the upper section 132. Each of the opposing staircases 304 of a respective SGD stadium structure 302 may individually include a desired quantity of steps 306. For clarity and ease of understanding the description, FIG. 2 illustrates only a particular quantity of steps 306 in the each of the opposing staircases 304 of the SGD stadium structure 302. However, it will be understood that each of the opposing staircases 304 of an individual SGD stadium structure 302 may include a greater or lesser quantity of the steps 206 than that illustrated.

In some embodiments, the SGD stadium structure 302 are formed within the horizontal area of the extension/SGD contact region 300 at the same time as the WL stadium structures 202 are formed within the horizontal area of the WL contact region 200. In some other embodiments, the SGD stadium structures 302 are formed within the horizontal area of the extension/SGD contact region 300, and then the WL stadium structures 202 are formed within the horizontal area of the WL contact region 200. In yet some further embodiments, the WL stadium structures 202 are formed within the horizontal area of the WL contact region 200, and then the SGD stadium structures 302 are formed within the horizontal area of the extension/SGD contact region 300.

Still referring to FIG. 2, the method may further include forming a first dielectric fill material 115 over the SGD stadium structures 302 in the extension/SGD contact region 300 and over the WL stadium structures 202 in the WL contact region 200. Uppermost boundaries (e.g., uppermost surfaces) of the first dielectric fill material 115 in the WL contact region 200 and the extension/SGD contact region 300 may be formed to be substantially coplanar with an uppermost boundary (e.g., an uppermost surface) of the upper section 132 of the preliminary stack structure 102. Following formation of the first dielectric fill material 115, the microelectronic device structure 100 may, optionally, be subjected to a chemical mechanical planarization (CMP) process to remove material (e.g., additional portions of the first dielectric fill material 115) overlying uppermost boundaries of the preliminary stack structure 102.

The first dielectric fill material 115 may be formed of and include at least one dielectric material having substantially similar etch selectivity to that of the insulative material 104 of the tiers 108 of the preliminary stack structure 102. By way of non-limiting example, the first dielectric fill material 115 may be formed of and include at least one oxygen-containing dielectric material, such as a one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric oxynitride material (e.g., SiOₓN_{y}), and at least one dielectric carboxynitride material (e.g., SiOₓC_{z}N_{y}). In some embodiments, the first dielectric fill material 115 is formed of and includes SiOₓ (e.g., SiO₂).

In FIG. 2 the first dielectric fill material 115 is depicted as being in direct physical contact with the WL stadium structures 202 and the SGD stadium structures 302. However, there may be at least one dielectric liner between the first dielectric fill material 115 and the WL stadium structures 202 and/or the SGD stadium structures 302.

Furthermore, in some other embodiments, at least some processing stages (and associated processing acts) different than those described above may be used to arrive at a configuration functionally substantially similar to that of the microelectronic device structure 100 shown in FIG. 2. By way of non-limiting example, in accordance with additional embodiments of the disclosure, an additional method of forming a microelectronic device of the disclosure may include forming the lower section 130 of the preliminary stack structure 102, forming the WL stadium structures 202 within the horizontal area of the WL contact region 200, forming implanted regions 210 within the portions of the sacrificial material 106 of at least some of the tiers 108 of the lower section 130 at the selected steps 206 of the WL stadium structure 202, and subsequently filling the trench above the WL contact region 200 with a first dielectric fill material 115. Thereafter, the upper section 132 of the preliminary stack structure 102 may be formed overlying lower section 130 of the preliminary stack structure 102. The SGD stadium structures 302 may be formed in the upper section 132 of the preliminary stack structure 102 and within the horizontal area of the extension/SGD contact region 300, followed by forming the first dielectric fill material 115 above the extension/SGD contact region 300.

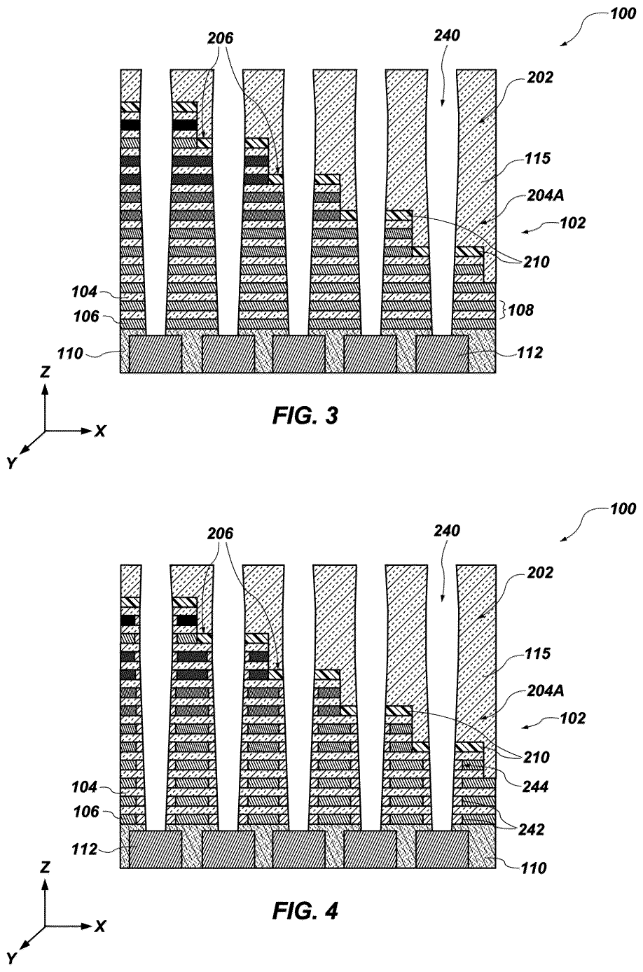

Referring next to FIG. 3, which illustrates an enlarged portion of dashed box A of FIG. 2 following the processing stage previously described with reference to FIG. 2, word line contact openings (also referred to herein as “WL openings”) 240 may be formed to extend from an upper surface of the first dielectric fill material 115 through an entire vertical extent (e.g., a height) of the preliminary stack structure 102 to the base structure 110 underlying the preliminary stack structure 102.

Portions of the first dielectric fill material 115 and the implanted regions 210, as well as portions of the insulative material 104 and the sacrificial material 106 of the tiers 108, may be removed by exposing the respective materials to wet etch chemistries and/or dry etch chemistries, for example, in one or more material removal processes. Portions of the material of the implanted regions 210 (e.g., central portions thereof) may be removed (e.g., etched) in one or more material removal processes, resulting in a dimension (e.g., width) of each of the WL contact openings 240 being relatively less than that of the width of the implanted regions 210. Accordingly, a height of each of the WL contact openings 240 in the vertical direction (e.g., the Z-direction) may be substantially similar to (e.g., substantially the same as) one another irrespective of horizontal orientation relative to the steps 206 of the WL stadium structure 202. Manufacturing processes may be simplified by forming the WL contact openings 240 to extend entirely through the vertical extent of the preliminary stack structure 102, without forming the WL contact openings 240 to extend to varying (e.g., differing) depths corresponding to various locations of the individual steps 206 of the WL stadium structure 202. As will be described herein, the WL contact openings 240 may be used to from conductive contacts 265 and the associated strapping structures.

Horizontal dimensions (e.g., in the X-direction, in the Y-direction) of each of the WL contact openings 240 may be relatively smaller than those of upper surfaces (e.g., treads) of the steps 206 of the WL stadium structure 202. For example, a horizontal dimension (e.g., width, diameter) of the WL contact openings 240 in a least one direction (e.g., the X-direction and/or the Y-direction) may be within a range of from about 100 nanometers (nm) to about 500 nm, such as from about 100 nm to about 150 nm, from about 150 nm to about 250 nm, from about 250 nm to about 350 nm, or from about 350 nm to about 500 nm. However, the disclosure is not so limited and the horizontal dimensions of the WL contact openings 240 may be different than those described above. In some embodiments, the horizontal dimensions of the WL contact openings 240 are selected and tailored to effect a size and shape of one or more features to be formed in the microelectronic device structure 100.

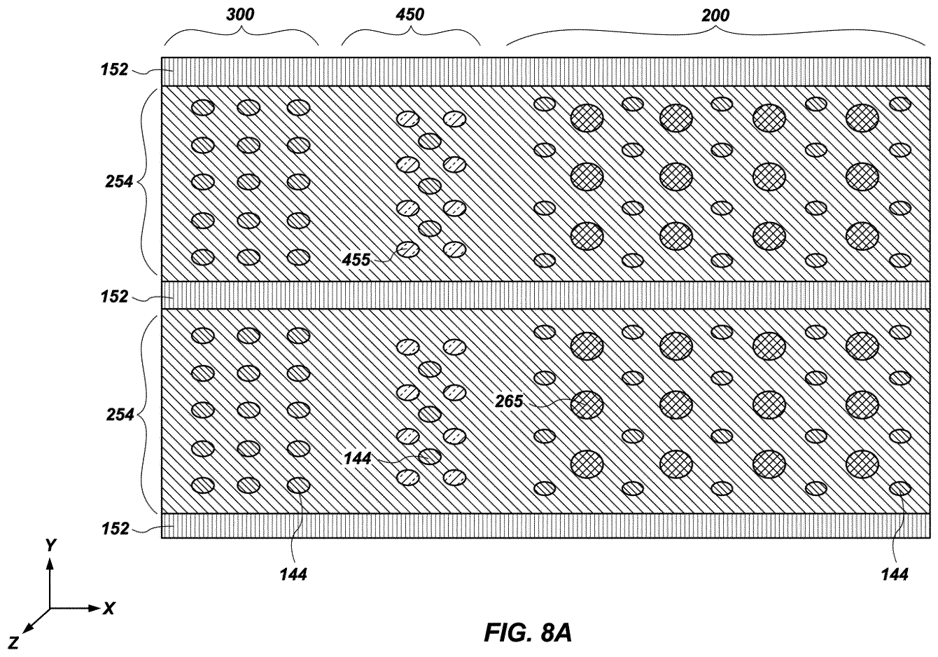

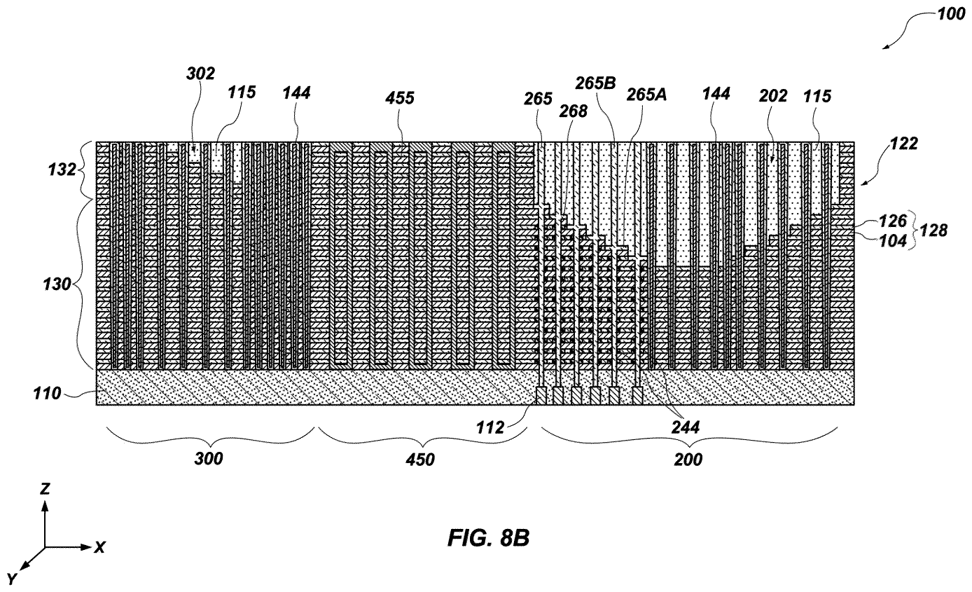

Referring next to FIG. 4, prior to forming materials of the conductive contacts 265 (FIG. 8B) within the WL contact openings 240, lateral (e.g., in the X-direction, in the Y-direction) portions of the sacrificial material 106 of the tiers 108 proximate the WL contact openings 240 may be converted to another insulative material to isolate remaining portions of the sacrificial material 106 of the tiers 108 from the WL contact openings 240. For example, the sacrificial material 106 (e.g., a silicon nitride material) of the tiers 108 may be oxidized to form a liner material 242. Accordingly, the liner material 242 may be directly laterally adjacent to (e.g., continuous with) remaining portions of the sacrificial material 106 of the tiers 108. In some such embodiments, the liner material 242 is formed of and includes an oxide material having a material composition that differs from that of the remaining portions of the sacrificial material 106, although other insulative materials may be employed for the liner material 242, so long as the liner material 242 exhibits an etch selectivity relative to the remaining portions of the sacrificial material 106.

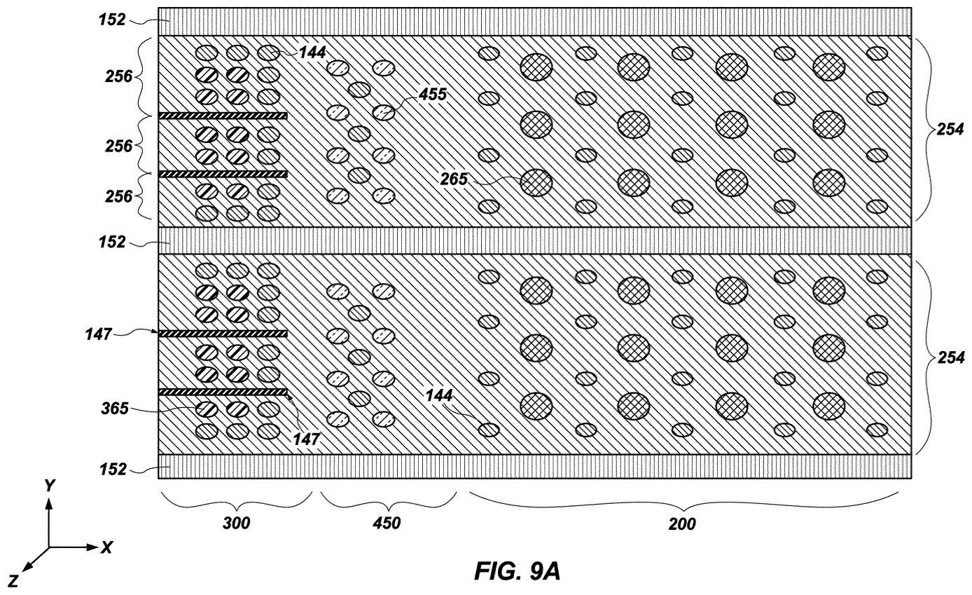

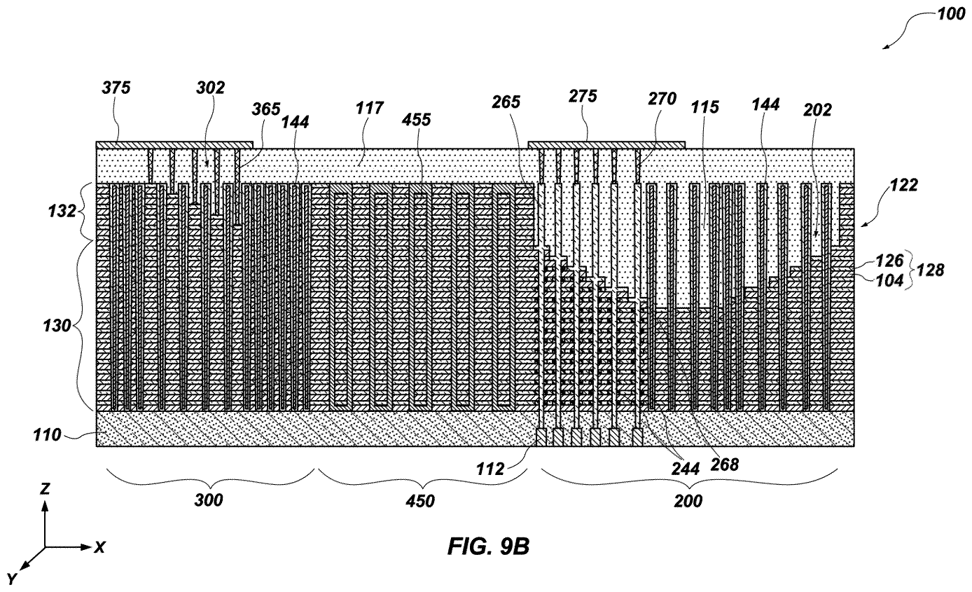

Formation of the liner material 242 may result in formation of isolation regions 244 between the WL contact openings 240 and the remaining portions of the sacrificial material 106 of the tiers 108, such that portions of the sacrificial material 106 of the tiers 108 having a first material composition are relatively remote (e.g., isolated) from the WL contact openings 240 by the liner material 242 of the isolation regions 244 having a second, different material composition. Thus, processing acts may be selected to provide (e.g., facilitate, promote) formation of the liner material 242 proximate the WL contact openings 240 for formation of the isolation regions 244 between the remaining portions of the horizontally neighboring sacrificial material 106 of the tiers 108 and the materials of conductive contacts 265 (FIG. 9B) subsequently formed within the WL contact openings 240.

Alternatively, the lateral portions of the sacrificial material 106 may be selectively removed through the WL contact openings 240 to form the recessed regions for formation of the isolation regions 244. By way of non-limiting example, exposed portions of the sacrificial material 106 may be exposed to an etchant (e.g., a wet etchant) through the WL contact openings 240 to selectively remove portions of the sacrificial material 106 with respect to the insulative material 104. In some embodiments, the sacrificial material 106 are exposed to phosphoric acid (H₃PO₄) to selectively remove portions of the sacrificial material 106 proximate the WL contact openings 240. After selectively removing portions of the sacrificial material 106, the liner material 242 may be formed within the recessed regions proximate the remaining portions of the sacrificial material 106 without fully filling the WL contact openings 240. For example, the liner material 242 may be formed within the recessed regions to effectively “pinch off” and close (e.g., seal) the recessed regions immediately adjacent to the WL contact openings 240. The liner material 242 may be formed to extend between vertically neighboring insulative material 104 proximate the recessed regions vacated by portions of the sacrificial material 106, such that the liner material 242 substantially vertically fills portions of the recessed regions proximate the WL contact openings 240 without entirely filling the WL contact openings 240. The liner material 242 may be formed by conventional techniques, such as one or more of in situ growth, CVD, ALD, and PVD using conventional processing equipment. In some embodiments, the liner material 242 is formed (e.g., deposited) using a single, continuous ALD process or a single, continuous CVD process.

The liner material 242 may be formed of and include one or more of the materials described above with reference to the insulative material 104 (e.g., SiO₂). For example, the liner material 242 may be formed of and include insulative material that is different than, and that exhibits etch selectivity with respect to, the remaining sacrificial material 106 and the implanted regions 210. In some embodiments, the liner material 242 is formed of and includes a single high quality silicon oxide material, such as an ALD SiOₓ. For example, the liner material 242 may be a substantially uniform and substantially conformal silicon oxide material (e.g., a substantially uniform and substantially conformal silicon dioxide material) so that substantially no voids are present in the liner material 242. The liner material 242 may, alternatively, be formed of and include one or more of silicon oxycarbide (SiOₓC_{y}), silicon oxynitride (SiOₓN_{y}), hydrogenated silicon oxycarbide (SiCₓO_{y}H_{z}), or silicon oxycarbonitride (SiOₓC_{y}N_{z}), for example.

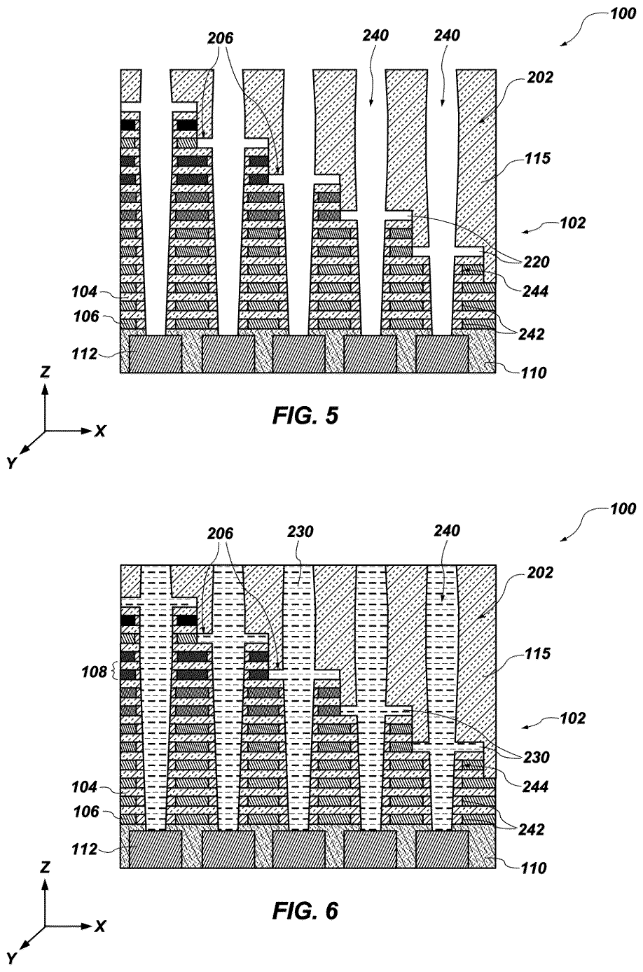

Referring next to FIG. 5, remaining portions of the material of the implanted regions 210 (FIG. 4) may, optionally, be selectively removed (e.g., exhumed) to form lateral openings 220 individually continuous with respective ones of the WL contact openings 240. For example, portions of the implanted regions 210 overlying the steps 206 of the WL stadium structure 202 may be at least partially (e.g., substantially entirely) removed to form the lateral openings 220. Removing the implanted regions 210 to form the lateral openings 220 effectively increases the horizontal width of portions of the WL contact openings 240 at the steps 206 of the WL stadium structure 202 within the preliminary stack structure 102. In additional embodiments, the remaining portions of the implanted regions 210 remain in the WL stadium structure 202 at the processing stage of FIG. 5 and are removed (e.g., exhumed) during subsequent material removal processes (e.g., replacement gate processing acts), as described below with reference to FIGS. 8A and 8B.

In some embodiments, the material (e.g., carbon-containing material, boron-containing material) of the implanted regions 210 is removed by exposing the material to one or more etchants, such as wet etchants, through the WL contact openings 240. The wet etchants may include one or more of phosphoric acid, acetic acid, nitric acid, hydrochloric acid, aqua regia, or hydrogen peroxide. In some embodiments, the material of the implanted regions 210 is removed by a phosphoric acid/acetic acid/nitric acid (PAN) etch chemistry. However, the disclosure is not so limited and the material of the implanted regions 210 may be removed with other etchants and/or material removal processes (e.g., vapor phase removal processes, atomic layer removal processes). For example, the material of the implanted regions 210 may be removed by performing a sequence of self-limiting processes of an atomic layer removal process to modify a surface of a material (e.g., the implanted regions 210), followed by selective removal of the modified surface material. In additional embodiments, the material of the implanted regions 210 is removed by a plasma etching process (e.g., an inductively coupled plasma (ICP) etching process) comprising one or more of hydrogen fluoride (HF), nitrogen trifluoride (NF₃), sulfur hexafluoride (SF₆), carbon tetrafluoride (CF₄), and another material. The material of the implanted regions 210 may, optionally, be exposed to hydrogen (H₂), nitrogen (N₂), oxygen (O₂), argon (Ar), or a combination thereof. The material of the implanted regions 210 may, alternatively, be removed by exposure to one or more dry etchants.

Referring next to FIG. 6, a first sacrificial fill material 230 may, optionally, be formed within one or more (e.g., each) of the WL contact openings 240 (FIG. 5) and the lateral openings 220 (FIG. 5). In some embodiments, the first sacrificial material fill material 230 is conformally formed within the WL contact openings 240 so as to be substantially continuous along a vertical dimension (e.g., a vertical height) of the preliminary stack structure 102, as well as within the lateral openings 220 so as to be substantially continuous along a horizontal dimension (e.g., a width) of the individual steps 206 of the WL stadium structure 202. In other embodiments, the first sacrificial fill material 230 is non-conformally formed within the WL contact openings 240 and the lateral openings 220. Accordingly, the first sacrificial fill material 230 may be formed to include varying (e.g., uneven) thicknesses throughout the WL contact openings 240 and the lateral openings 220. Further, the first sacrificial fill material 230 may be formed to include segmented (e.g., discontinuous) portions thereof, such that regions of the WL contact openings 240 and the lateral openings 220 include the first sacrificial fill material 230 and additional regions thereof do not include the first sacrificial fill material 230. In additional embodiments, the first sacrificial fill material 230 is formed within the WL contact openings 240 without being formed in the lateral openings 220, such as when the remaining portions of the implanted regions 210 remain in the WL stadium structure 202 at the processing stage of FIG. 4. In some instances, voids (e.g., gaps, seams) are formed within the first sacrificial fill material 230 during fabrication of the microelectronic device structure 100. For example, the first sacrificial fill material 230 may include one or more of the voids during formation thereof when the WL contact openings 240 exhibit a relatively high aspect ratio (HAR).

The first sacrificial fill material 230 may be formed of and include insulative material, such as dielectric nitride material. In some embodiments, the material of the first sacrificial fill material 230 includes one or more of the materials described above with reference to the sacrificial material 106 (e.g., Si₃N₄) of the tiers 108 of the preliminary stack structure 102. In additional embodiments, the first sacrificial fill material 230 includes one or more of semiconductive material and conductive material. For example, the first sacrificial fill material 230 may be formed to include semiconductive material, such as one or more of amorphous silicon and polycrystalline silicon. In some such embodiments, the semiconductive material of the first sacrificial fill material 230 is doped with one or more dopants, such as with at least one n-type dopant (e.g., one or more of arsenic, phosphorous, antimony, and bismuth) or at least one p-type dopant (e.g., one or more of boron, aluminum, and gallium).

The first sacrificial fill material 230 may be in contact with one or more (e.g., each) of the first dielectric fill material 115, the insulative material 104 and the sacrificial material 106 of the tiers 108 of the preliminary stack structure 102, the liner material 242 of the isolation regions 244, and the conductive structures 112. Accordingly, the first sacrificial fill material 230 may be formed to extend from the upper surface of the first dielectric fill material 115 to the conductive structures 112 underlying the preliminary stack structure 102 within the WL contact openings 240.

The first sacrificial fill material 230 may be configured and positioned to protect the materials (e.g., the first dielectric fill material 115, the insulative material 104, the liner material 242 of the isolation regions 244, the conductive structures 112) defining the WL contact openings 240 (FIG. 5) and the lateral openings 220 (FIG. 5) from being removed (e.g., exhumed) through the WL contact openings 240 during the subsequent material removal processes preformed on the preliminary stack structure 102. At least partially filling the WL contact openings 240 and lateral openings 220 with the first sacrificial fill material 230 may also substantially inhibit (e.g., impede, prevent) formation of additional dielectric material (e.g., carbon-containing mask material) during subsequent processing acts. Following formation of the first sacrificial fill material 230, the microelectronic device structure 100 may, optionally, be subjected to a chemical mechanical planarization (CMP) process to remove material (e.g., additional portions of the first sacrificial fill material 230) overlying the preliminary stack structure 102. Alternatively, the first sacrificial fill material 230 may not be formed at the processing stage of FIG. 6, such that the WL contact openings 240 and the lateral openings 220 remain open during the subsequent processing acts (e.g., replacement gate processing acts).

Referring collectively to FIG. 7A and FIG. 7B, which are respectively a simplified, partial top-down view and a simplified, vertical cross-sectional view of the microelectronic device structure 100 following the processing stage previously described with reference to FIG. 6, slots 151 (e.g., slits, openings) may be formed to vertically extend (e.g., in the Z-direction) though the preliminary stack structure 102 (FIG. 6), such as through the first dielectric fill material 115 of the WL contact region 200 and the extension/SGD contact region 300, and the tiers 108 (FIG. 6) of the insulative material 104 and the sacrificial material 106. Selected portions of each of the first dielectric fill material 115 in the WL contact region 200 and the extension/SGD contact region 300, as well as the tiers 108 of the insulative material 104 and the sacrificial material 106 may be removed by exposing the respective materials to wet etch chemistries and/or dry etch chemistries, while the unselected portions of the first dielectric fill material 115 in the WL contact region 200, the extension/SGD contact region 300, and the preliminary stack structure 102 may, optionally, be covered with an additional dielectric material and/or mask material (e.g., carbon-containing mask material) configured and positioned to protect the unselected portions thereof from being removed (e.g., exhumed) during the material removal processes.

The slots 151 may also be referred to herein as “replacement gate slots,” since they facilitate the replacement of the sacrificial material 106 with conductive material 126 as will be described in FIGS. 8A and 8B.

While the slots 151 are illustrated herein as being formed after formation of the first sacrificial fill material 230, it is understood that the slots 151 may, alternatively, be formed before formation of the first sacrificial fill material 230. Furthermore, the slots 151 may be formed during (e.g., substantially simultaneous with) formation of the WL contact openings 240.

The preliminary stack structure 102 may be partitioned (e.g., divided, segmented) to form blocks 254 separated from one another by the slots 151. The blocks 254 of the preliminary stack structure 102 may be formed to horizontally extend parallel in an X-direction. As used herein, the term “parallel” means substantially parallel. Horizontally neighboring blocks 254 of the preliminary stack structure 102 may be separated from one another in a Y-direction orthogonal to the X-direction by the slots 151. The slots 151 may also horizontally extend parallel in the X-direction. Each of the blocks 254 of the preliminary stack structure 102 may exhibit substantially the same geometric configuration (e.g., substantially the same dimensions and substantially the same shape) as each other of the blocks 254, or one or more of the blocks 254 may exhibit a different geometric configuration (e.g., one or more different dimensions and/or a different shape) than one or more other of the blocks 254. In addition, each pair of horizontally neighboring blocks 254 of the preliminary stack structure 102 may be horizontally separated from one another by substantially the same distance (e.g., corresponding to a width in the Y-direction of each of the slots 151) as each other pair of horizontally neighboring blocks 254 of the preliminary stack structure 102, or at least one pair of horizontally neighboring blocks 254 of the preliminary stack structure 102 may be horizontally separated from one another by a different distance than that separating at least one other pair of horizontally neighboring blocks 254 of the preliminary stack structure 102. In some embodiments, the blocks 254 of the preliminary stack structure 102 are substantially uniformly (e.g., substantially non-variably, substantially equally, substantially consistently) sized, shaped, and spaced relative to one another.

Although FIG. 7A illustrates only three (3) slots 151 and only two (2) blocks 254, the disclosure is not so limited. The microelectronic device structure 100 may include a plurality of (e.g., four, five, six, eight) blocks 254, each separated from laterally neighboring (e.g., in the Y-direction) blocks 254 by one of the slots 151. The slots 151 may divide the microelectronic device structure 100 into any desired quantity of blocks 254.

Still referring collectively to FIGS. 7A and 7B, an arrangement of support pillars 144 may be formed in select areas of the preliminary stack structure 102, such as in the extension/SGD contact region 300, the transition region 450, the WL contact region 200, and the array region. The array region is omitted from FIG. 7A for clarity and ease of understanding the drawings and associated description. For further clarity and ease of understanding the drawings and associated description, in FIG. 7B the support pillars 144 are omitted from the area of the forward staircases 204A (FIG. 2) of the WL stadium structure 202 in the WL contact region 200 of the microelectronic device structure 100. However, it will be understood that any desirable quantity and distribution of the support pillars 144 may be formed within the microelectronic device structure 100.

The support pillars 144 may individually be formed to vertically extend from or proximate an upper boundary of the preliminary stack structure 102, through the preliminary stack structure 102, and to or beyond a lower boundary of the preliminary stack structure 102. At least some of the support pillars 144 may be configured and positioned to facilitate support of the insulative material 104 of each of the tiers 108 of the preliminary stack structure 102 during subsequent removal of the sacrificial material 106 of the tiers 108, as described in further detail below. In some embodiments, the support pillars 144 are configured to be electrically non-operable, such that the support pillars 144 may not directly physically connect to other electrically operable, conductive components of the device.

In some embodiments, each block 254 of the preliminary stack structure 102 includes at least one array of the support pillars 144 vertically extending therethrough, including rows of the support pillars 144 extending in the X-direction, and columns of the support pillars 144 extending to the Y-direction. As a non-limiting example, for an individual block 254, an array of the support pillars 144 formed therein may include at least two (2) rows (e.g., at least four (4) rows) of the support pillars 144 each extending in the X-direction. In some embodiments, each block 254 of the preliminary stack structure 102 individually includes at least one array of the support pillars 144 exhibiting at least four (4) rows of the support pillars 144.

The support pillars 144 may each individually be formed to exhibit a desired horizontal cross-sectional shape. In some embodiments, each of the support pillars 144 is formed to exhibit a substantially circular horizontal cross-sectional shape. In additional embodiments, one or more (e.g., each) of the support pillars 144 exhibits a non-circular cross-sectional shape, such as one of more of a square cross-sectional shape, a rectangular cross-sectional shape, an oblong cross-sectional shape. In addition, each of the support pillars 144 may be formed to exhibit substantially the same horizontal cross-sectional dimensions (e.g., substantially the same horizontal diameter), or at least one of the support pillars 144 may be formed to exhibit one or more different horizontal cross-sectional dimensions (e.g., a different horizontal diameter) than at least one other of the support pillars 144. In some embodiments, all of the support pillars 144 are formed to exhibit substantially the same horizontal cross-sectional dimensions.

The support pillars 144 may each individually be formed of and include at least one conductive material, such as one or more of at least one metal (e.g., W, Ti, Mo, Nb, V, Hf, Ta, Cr, Zr, Fe, Ru, Os, Co, Rh, Ir, Ni, Pd, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni-and Fe-based alloy, an Al-based alloy, a Cu-based alloy, a Mg-based alloy, a Ti-based alloy, a steel, a low-carbon steel, a stainless steel), at least one conductive metal-containing material (e.g., a conductive metal nitride, a conductive metal silicide, a conductive metal carbide, a conductive metal oxide), and at least one conductively-doped semiconductor material (e.g., conductively-doped Si, conductively-doped Ge, conductively-doped SiGe). In addition, at least one insulative liner material may be formed to horizontally interpose between the support pillars 144 and the insulative material 104 and the sacrificial material 106 of tiers 108 of the preliminary stack structure 102. The insulative liner material may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the insulative liner material comprises SiO₂.

In addition, an arrangement of deep contact structures 455 including conductive material may be formed in select areas of the preliminary stack structure 102, such as within the transition region 450, as shown in FIGS. 7A and 7B.

Referring next to FIGS. 8A and 8B, which are respectively the simplified, partial top-down view and the simplified, vertical cross-sectional view of the microelectronic device structure 100 following the processing stage previously described with reference to FIGS. 7A and 7B, the slots 151 may facilitate the replacement of the sacrificial material 106 (FIG. 7B) of the tiers 108 with conductive material 126, as well as the selective removal of the first sacrificial fill material 230 within the WL contact region 200 (FIGS. 7A and 7B), if present.

The sacrificial material 106 (FIG. 7B) of tiers 108 (FIG. 7B) of the preliminary stack structure 102 (FIG. 7B) may be selectively removed (e.g., exhumed) through the slots 151 (FIG. 7A). Further, the first sacrificial fill material 230 of the WL contact region 200 may be selectively removed (e.g., exhumed) through the slots 151. For example, the first sacrificial fill material 230 may be removed during (e.g., substantially simultaneous with) removal of the sacrificial material 106. In embodiments including the implanted regions 210 remaining within a horizontal area of the WL stadium structure 202 at the processing stage of FIG. 7B, the remaining portions of the implanted regions 210 may be selectively removed (e.g., exhumed) through the cell openings between the insulative material 104 during (e.g., substantially simultaneous with) removal of the sacrificial material 106 and the first sacrificial fill material 230 to reduce cost and the number of processing acts conducted.

As shown in FIG. 8B, the sacrificial material 106 (FIG. 7B) of the tiers 108 (FIG. 7B) of the preliminary stack structure 102 (FIG. 7B) may be at least partially (e.g., substantially) replaced with the conductive material 126 to form a stack structure 122 comprising tiers 128 respectively including a level of the conductive material 126 vertically neighboring a level of the insulative material 104 through so-called “replacement gate” or “gate last” processing acts. Within the stack structure 122, the conductive material 126 may be vertically interleaved with (e.g., may vertically alternate with) the insulative material 104.

In some embodiments, the conductive material 126 of the tiers 128 of the stack structures 122 comprises tungsten (W). In other embodiments, the conductive material 126 of the tiers 128 of the stack structures 122 comprises conductively doped polysilicon. In yet other embodiments, the conductive material 126 of the tiers 128 of the stack structures 122 comprise one or more of titanium, ruthenium, aluminum, and molybdenum. For each of the tiers 128, the conductive material 126 thereof may be substantially homogeneous or may be substantially heterogeneous. In some embodiments, for each of the tiers 128, the conductive material 126 thereof is substantially homogeneous. In additional embodiments, for at least one of the tiers 128, the conductive material 126 thereof is heterogeneous. Optionally, at least one liner material (e.g., at least one insulative liner material, at least one conductive liner materials) may be formed around the conductive material 126 of one or more tier 128 of the stack structure 122. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive material 126. In some embodiments, the liner material further includes high-K dielectric material. In additional embodiments, the liner material comprises titanium nitride (TiNₓ, such as TiN). In further embodiments, the liner material further includes aluminum oxide (AlOₓ, such as Al₂O₃). As a non-limiting example, for each of the blocks 254 of the stack structure 122, AlOₓ (e.g., Al₂O₃) may be formed directly adjacent the insulative material 104 of the tiers 128, TiNₓ (e.g., TiN) may be formed directly adjacent the AlOₓ, and W may be formed directly adjacent the TiNₓ. For clarity and ease of understanding the description, the liner material is not illustrated in FIG. 8B, but it will be understood that the liner material may be disposed around the conductive material 126 of the stack structure 122.

As shown in FIG. 8A, after the replacement gate processing acts, the slots 152 may be at least partially (e.g., substantially) filled with at least one dielectric material (e.g., at least one dielectric oxide material, such as SiOₓ; at least one dielectric nitride material, such as SiN_{y}) to form a first dielectric-filled slot structure 152. The dielectric material may be formed of and include insulative material, such as one or more of dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). A material composition of the dielectric material may be substantially the same as a material composition of one or more of the first dielectric fill material 115 of the WL contact region 200 and the extension/SGD contact region 300, and the insulative material 104 of the stack structure 122. Alternatively, the material composition of the dielectric material may be different than the material composition of the first dielectric fill material 115 of the WL contact region 200 and the extension/SGD contact region 300, and the insulative material 104 of the stack structure 122. In some embodiments, the first dielectric-filled slot structure 152 are formed of and include SiOₓ (e.g., SiO₂). The first dielectric-filled slot structure 152 may individually be formed to be substantially homogeneous, or may individually be formed to be heterogeneous.

The conductive material 126 of at least one vertically (e.g., in the Z-direction) lower tier 128 of the stack structure 122 may be employed as a source-side select gate (SGS) structures of the microelectronic device structure 100. In some embodiments, the conductive material 126 of a single (e.g., only one), vertically lowermost tier 128 of the stack structure 122 is employed for SGS structures for blocks 254 of the microelectronic device structure 100. In addition, within individual blocks 254 of the stack structure 122, the conductive material 126 of one or more relatively vertically upper tiers 128 of the stack structure 122 may be employed for drain-side select gate (SGD) structures of the microelectronic device structure 100.

As shown in FIGS. 8A and 8B, the first sacrificial fill material 230 (FIGS. 7A and 7B) in the WL contact openings 240 (FIGS. 7A and 7B) and the lateral openings 220 (FIGS. 7A and 7B) of the WL contact region 200 may also be removed (e.g., through the processing acts of the replacement gate process, the processing acts preceding the replacement gate process, or processing acts followed the replacement gate process). The resulting WL contact openings 240 may be substantially filled with one or more conductive fill materials to form the conductive contacts 265 (e.g., WL contacts). The conductive fill material for the conductive contacts 265 (as well as additional conductive additional conductive contacts 365, such as SGD contacts, which will be also be described herein) may include one or more of at least one metal (e.g., one or more of tungsten, titanium, nickel, platinum, rhodium, ruthenium, iridium, aluminum, copper, molybdenum, silver, gold), at least one alloy (e.g., an alloy of one or more of the aforementioned metals), at least one metal-containing material that includes one or more of the aforementioned metals (e.g., metal nitrides, metal silicides, metal carbides, metal oxides, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), alloys thereof), at least one conductively-doped semiconductor material (e.g., conductively-doped silicon, conductively-doped germanium, conductively-doped silicon germanium), polysilicon, and at least one other material exhibiting electrical conductivity.

Once formed, each of the conductive contacts 265 may vertically extend completely through the stack structure 122 without terminating on the steps 206 of the WL stadium structure 202. For example, each of the conductive contacts 265 may vertically extend (e.g., in the Z-direction) from a vertically uppermost boundary of the first dielectric fill material 115 (e.g., at an elevational level of a vertically uppermost tier 128 of the stack structure 122), through the entire vertical extent of the stack structure 122, and to terminate at the conductive structures 112. Since all of the conductive contacts 265 terminate at the single location (e.g., at or within the conductive structures 112), damage within the WL stadium structure 202 during fabrication may be substantially reduced (e.g., substantially prevented). Accordingly, manufacturing processes may be simplified by forming the conductive contacts 265 to extend entirely through the vertical extent of the stack structure 122 and to terminate at a single location, without forming the conductive contacts 265 to extend to varying (e.g., differing) depths of the individual steps 206 of the WL stadium structure 202. In contrast, conventional microelectronic device structures include conductive contacts (e.g., WL contacts) that terminate at (e.g., land on) the upper surfaces (e.g., treads) of individual steps of WL staircase structures, resulting in varying heights of the conductive contacts throughout the WL staircase structures.

During the formation of the conductive contacts 265, the conductive fill material thereof may also substantially fill the lateral openings 220 to form the strapping structures 268. The conductive contacts 265 may be integral and continuous (e.g., unitary) with the strapping structures 268. The strapping structures 268 may horizontally project outward from and be continuous with the conductive contacts 265. The conductive fill material of respective ones of the strapping structures 268 may be in contact with each of the first dielectric fill material 115, the underlying insulative material 104 of a respective one of the tiers 128 of the stack structure 122, as well as with the horizontal neighboring conductive material 126 of the respective one of the tiers 128 of the stack structure 122.

The conductive contacts 265 and the strapping structures 268 may individually be formed of and include conductive material. By way of non-limiting example, the conductive contacts 265 and the strapping structures 268 may be formed of and include one or more of polysilicon, tungsten, titanium, titanium nitride, or another material. In some embodiments, the conductive fill material of the conductive contacts 265 and the strapping structures 268 comprises polysilicon. In some such embodiments, the conductive fill material of the conductive contacts 265 and the strapping structures 268 is doped with one or more dopants, such as with at least one n-type dopant (e.g., one or more of arsenic, phosphorous, antimony, and bismuth) or at least one p-type dopant (e.g., one or more of boron, aluminum, and gallium). In other embodiments, the conductive fill material of the conductive contacts 265 and the strapping structures 268 comprises tungsten. The conductive fill material of the conductive contacts 265 and the strapping structures 268 may or may not include substantially the same material composition as the conductive material 126 of the stack structure 122.

The strapping structures 268 may be considered portions (e.g., outwardly horizontally projecting portions) of the conductive contacts 265. For example, as shown in FIG. 8B, the conductive contacts 265 may individually include a first portion 265A, which corresponds to one of the strapping structures 268. In addition, the conductive contacts 265 may also individually include a second portion 265B in electrical communication with the conductive structures 112 without being in electrical communication with the conductive material 126 of more than one of the tiers 128 of the stack structure 122, such as the conductive material 126 of tiers 128 vertically underlying (e.g., in the Z-direction) the individual first portion 265A. The first portion 265A respective ones of the conductive contacts 265 is in electrical communication with the second portion 265B thereof and with the conductive material 126 of a respective one of the tiers 128 of the stack structure 122. For example, the conductive material 126 of an individual tier 128 of the stack structure 122 vertically overlapping the strapping structure 268 may be configured as a contact region conductive contact 265 operatively associated (e.g., unitary) with the strapping structure 268. The size and location of the first portions 265A of the conductive contacts 265 (and, hence, the strapping structures 268) may correspond to the size and location of the lateral openings 220 (FIG. 5), and the size and location of the second portions 265B of the conductive contacts 265 may correspond to the size and location of the WL contact openings 240 (FIG. 5).

As shown in FIG. 8B, relative to an individual strapping structure 268, one or more side surfaces (e.g., lateral side surfaces, horizontal side surfaces) of the liner material within the isolation regions 244 may directly contact side surfaces of the conductive material 126 of the tiers 128 of the stack structure 122 vertically underlying the strapping structure 268. The liner material within the isolation regions 244 electrically isolates the conductive material an individual conductive contact 265 from the conductive material 126 different ones of the tiers 128 vertically underlying the strapping structure 268 operatively associated (e.g., unitary) with conductive contact 265.

Accordingly, an individual conductive contact 265 may be configured to facilitate an electrical communication between an individual conductive structure 112 and an individual conductive material 126 horizontally neighboring and coupled to (e.g., unitary with, continuous with) the strapping structure 268 (and, hence, with the conductive material 126 of an individual tier 128 of the stack structure 122 vertically overlapping the strapping structure 268). Further, the strapping structure 268 for at least one of the conductive contacts 265 is vertically offset from the strapping structure 268 for at least one other of the conductive contacts 265. Forming the conductive contacts 265 to individually facilitate electrical communication between one of the conductive structures 112 and the conductive material 126 of one of the tiers 128 of the stack structure 122 may reduce a quantity of support structures (e.g., support pillars 144) present within the WL contact region 200 as compared to conventional configurations. The configurations of the conductive contacts 265 and strapping structures 268 of the disclosure may also facilitate forming support structures proximate the conductive contacts 265 without the need to form complex conductive routing pathways above the stack structure 122. Accordingly, within an individual block 254, a greater quantity of the steps 206 of a WL stadium structure 202 may be provided within a given horizontal area as compared to conventional configurations. As mentioned above, by providing the conductive contacts 265 and strapping structures 268 (e.g., effectively the second portions 265B of the conductive contacts 265) within a horizontal area of the WL stadium structure 202, such configurations may permit reduced congestion in conductive routing pathways above the stack structure 122. By reducing congestion in conductive routing pathways above the stack structure 122, horizontal spacing of conductive features above the stack structure 122 may be increased, resulting in a decrease in parasitic (e.g., stray) capacitance between horizontally neighboring conductive features during use and operation of the microelectronic device structure 100.

Furthermore, by forming the strapping structures 268 during formation of the conductive contacts 265 (e.g., as the second portions 265B of the conductive contacts 265), manufacturing processes may be simplified and costs may be reduced. The strapping structures 268 (e.g., the conductive fill material thereof) may be formed during (e.g., substantially simultaneous with) formation of the conductive contacts 265 using a single, continuous CVD process or a single, continuous PVD process, for example, without forming the strapping structures 268 using an ALD process, similar to that used during the replacement gate processing acts. Additionally, the methods and structures of the disclosure may reduce the risk of damage during the formation of devices of the disclosure and may effectuate increased yield and decreased current leakage (e.g., which may otherwise result from undesirable damage) as compared to conventional methods, conventional structures, and conventional devices.

Referring next collectively to FIGS. 9A and 9B, a second dielectric fill material 117 may be formed over the first dielectric fill material 115 and the stack structure 122. An uppermost boundary of the second dielectric fill material 117 may vertically overlie (e.g., in the Z-direction) uppermost boundaries (e.g., an uppermost surface) of an uppermost tier 128 of the stack structure 122. A material composition of the second dielectric fill material 117 may be substantially the same as a material composition of the first dielectric fill material 115 and/or the first dielectric-filled slot structure 152, or the material composition of the second dielectric fill material 117 may be different than the material composition of the first dielectric fill material 115 and/or the first dielectric-filled slot structure 152. In some embodiments, the second dielectric fill material 117 is formed of and includes SiOₓ (e.g., SiO₂).

Within horizontal areas of respective ones of the blocks 254 of the stack structure 122, one or more second dielectric-filled slot structures 147 (e.g., dielectric-filled SGD openings) may be formed within the extension/SGD contact region 300 of the microelectronic device structure 100. For an individual block 254 of the stack structure 122, the second dielectric-filled slot structures 147 may segment the conductive material 126 of at least some of the tiers 128 within the upper section 132 of the stack structure 122 into sub-blocks 256. Each block 254 of the stack structure 122 may include greater than or equal to one (1) of the second dielectric-filled slot structures 147 within a horizontal area thereof. The second dielectric-filled slot structure 147 may sub-divide each block 254 into at least two (2) sub-blocks 256. For example, as shown in FIG. 9A, if an individual block 254 includes two (2) of the second dielectric-filled slot structures 147 within a horizontal area thereof, the second dielectric-filled slot structures 147 may sub-divide the block 254 into three (3) sub-blocks 256. For an individual block 254, portions of the conductive material 126 of individual tiers 128 within the upper section 132 of the preliminary stack structure 102 and within horizontal areas of the sub-blocks 256 of the block 254 may form the upper select gate structures (e.g., SGD structures) of the block 254 for upper select transistors (e.g., drain-side select transistors) formed within an array region of the block 254 horizontally neighboring the SGD contact region.

A material composition of each of the second dielectric-filled slot structures 147 may be substantially the same as a material composition of each of the first dielectric-filled slot structures 152, or the material composition one or more of the second dielectric-filled slot structures 147 may be different than the material composition of one or more of the first dielectric-filled slot structure 152. In some embodiments, the second dielectric-filled slot structures 147 are respectively formed of and include at least one dielectric oxide material (e.g., SiOₓ, such as SiO₂).

The second dielectric-filled slot structures 147 may be formed within the extension/SGD contact region 300 to extend vertically (e.g., in Z-direction) into the upper section 132 of the stack structure 122. As a non-limiting example, the second dielectric-filled slot structures 147 may individually vertically extend into less than or equal to eight (8) relatively higher tiers 128 (e.g., from one (1) relatively vertically higher tier 128 to eight (8) relatively vertically higher tiers 128) of the stack structure 122. Accordingly, for an individual block 254 of the stack structure 122, the conductive material 126 of less than or equal to eight (8) relatively higher tiers 128 may be employed as upper select gate structures (e.g., SGD structures) of the block 254. In addition, for an individual block 254, the second dielectric-filled slot structures 147 may horizontally extend (e.g., in the X-direction) through the array region and at least partially into the extension/SGD contact region 300. For an individual block 254, the second dielectric-filled slot structures 147 may horizontally extend (e.g., in X-direction) at least into a horizontal area of one of the staircases (e.g., the forward staircase 204A) of the SGD stadium structure 302 of the block 254.

Still referring collectively to FIGS. 9A and 9B, for an individual block 254 of the stack structure 122, the conductive material 126 of at least some of the tiers 128 within the lower section 130 of the stack structure 122 may be employed as access line structures (e.g., word line structures) of the block 254. Moreover, for an individual block 254 of the stack structure 122, the conductive material 126 of at least a vertically lowest tier 128 within the lower section 130 of the stack structure 122 may be employed as at least one lower select gate structure (e.g., at least one source-side select gate (SGS) structure) for lower select transistors (e.g., source-side select transistors) within the array region of the block 254.

As shown in FIG. 9B, additional conductive contacts 365 (e.g., SGD contacts) may be formed in the extension/SGD contact region 300 to vertically extend to and contact the conductive material 126 of at least some of the tiers 128 within the upper section 132 of the stack structure 122. Some of the additional conductive contacts 365 may be formed to vertically extend through the second dielectric fill material 117 to contact (e.g., physically contact, electrically contact) at the conductive material 126 of the at least some of the tiers 128 at some of the steps 306 of the SGD stadium structure 302. For clarity and ease of understanding the drawings and associated description, the microelectronic device structure 100 of FIG. 9B is shown as having the additional conductive contacts 365 only on the forward staircase and the central area of the SGD stadium structure 302. However, it is to be understood that any desirable quantity and distribution of the additional conductive contacts 365 may be formed on the SGD stadium structure 302 of the microelectronic device structure 100. For example, the additional conductive contacts 365 may be formed on at least one of the forward staircase, the reverse staircase, and the central area of the SGD stadium structure 302.

Desirable arrangements of the additional conductive contacts 365 may be formed within a horizontal area of the SGD stadium structure 302 of an individual block 254 of the stack structure 122. In some embodiments, within a horizontal area of the SGD stadium structure 302 of an individual block 254, each sub-block 256 of the block 254 includes a row of the additional conductive contacts 365 horizontally extending in the X-direction. In addition, as depicted in FIG. 9A, within an individual block 254 of the stack structure 122 columns of the additional conductive contacts 365 may horizontally extend in the Y-direction, wherein different additional conductive contacts 365 of an individual column are located in different sub-blocks 256 of the block 254 than one another.

The additional conductive contacts 365 may each individually be formed to exhibit a desired horizontal cross-sectional shape. In some embodiments, each of the additional conductive contacts 365 is formed to exhibit a substantially circular horizontal cross-sectional shape. In additional embodiments, one or more (e.g., each) of the additional conductive contacts 365 exhibits a non-circular cross-sectional shape, such as one more of an oblong cross-sectional shape, an elliptical cross-sectional shape, a square cross-sectional shape, a rectangular cross-sectional shape. In addition, each of the additional conductive contacts 365 may be formed to exhibit substantially the same horizontal cross-sectional dimensions (e.g., substantially the same horizontal diameter), or at least one of the additional conductive contacts 365 may be formed to exhibit one or more different horizontal cross-sectional dimensions (e.g., a different horizontal diameter) than at least one other of the additional conductive contacts 365. In some embodiments, all of the additional conductive contacts 365 are formed to exhibit substantially the same horizontal cross-sectional dimensions.

The additional conductive contacts 365 may be formed of and include conductive material. As a non-limiting example, the additional conductive contacts 365 may be formed of and include one or more of at least one metal, at least one alloy, and at least one conductive metal-containing material (e.g., a conductive metal nitride, a conductive metal silicide, a conductive metal carbide, a conductive metal oxide). A material composition of the additional conductive contacts 365 may be substantially the same as a material composition of the conductive material 126 of the tiers 128 of the stack structure 122, or the material composition of the additional conductive contacts 365 may be different than the material composition of the conductive material 126 of the tiers 128 of the stack structure 122. In some embodiments, the additional conductive contacts 365 are individually formed of and include tungsten (W).

As shown in FIG. 9B, conductive routing structures 375 may be formed over (e.g., directly on) and in electrical communication with the additional conductive contacts 365. The conductive routing structures 375 may be formed of and include a conductive material. In some embodiments, the conductive routing structures 375 respectively comprise tungsten (W). The conductive routing structures 375 may or may not include substantially the same material composition as the conductive material 126 of the tiers 128 of the stack structure 122.

Further, interconnect structures 270 may be formed to vertically extend through the second dielectric fill material 117 to the conductive contacts 265. The interconnect structures 270 may individually vertically overlie (e.g., directly on) be in electrical communication with respective a respective one of the conductive contacts 265. In addition, additional conductive routing structures 275 may be formed over (e.g., directly on) and in electrical communication with the interconnect structures 270. Each of the interconnect structures 270 may vertically intervene between and be coupled to a respective one of the conductive contacts 265 and a respective one of the additional conductive routing structures 275.

The interconnect structures 270 may be formed of and include conductive material, such as one or more of the materials described above with reference to the conductive material 126 of the tiers 128 of the stack structure 122. In some embodiments, the interconnect structures 270 comprise tungsten (W). Each of the interconnect structures 270 may individually include a substantially homogeneous distribution or a substantially heterogeneous distribution of conductive material. In some embodiments, each of the interconnect structures 270 is substantially homogeneous (e.g., includes a single material).

The additional conductive routing structures 275 may be formed of and include conductive material. In some embodiments, the additional conductive routing structures 275 comprise tungsten (W). The additional conductive routing structures 275 may or may not include substantially the same material composition as the interconnect structures 270 and/or the conductive material 126 of the tiers 128 of the stack structure 122.

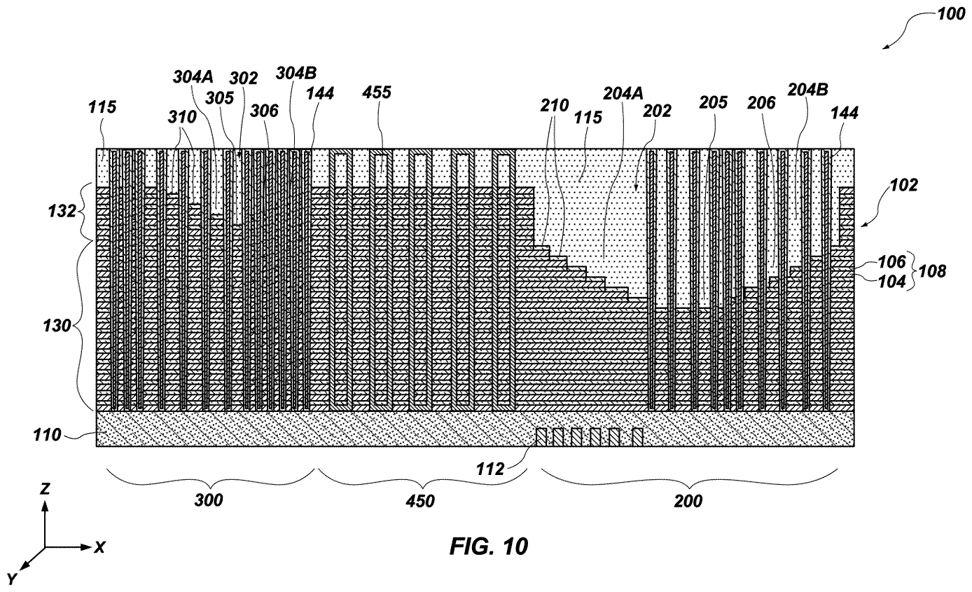

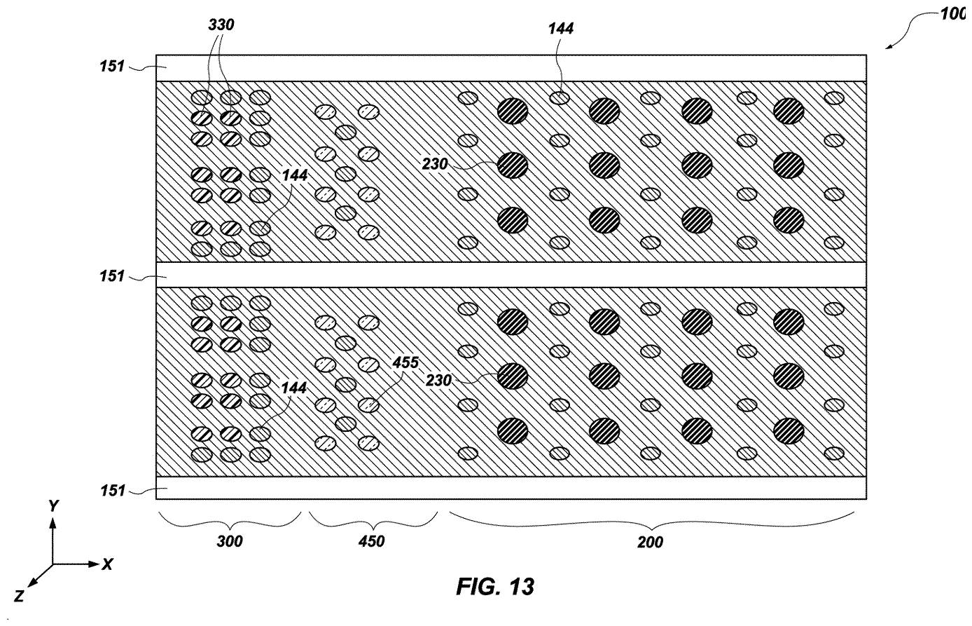

FIGS. 10 through 14 are simplified, partial vertical cross-sectional views (FIGS. 10-12 and 14) and a simplified, partial top-down view (FIG. 13) illustrating different processing stages of a method of forming a microelectronic device (e.g., a memory device, such as a three-dimensional (3D) NAND Flash memory device), in accordance with some additional embodiments of the disclosure. With the description provided below, it will be readily apparent to one of ordinary skill in the art that the methods and structures described herein with reference to FIGS. 10 through 14 may be used in the formation and configuration of various devices and electronic systems. In other words, the methods of the disclosure may be used whenever it is desired to form a microelectronic device.

Referring to FIG. 10, a method for forming a microelectronic device according to some other embodiments may include forming a preliminary stack structure 102 over a base structure 110 comprising conductive structures 112 (e.g., conductive routing structures, conductive line structures). The preliminary stack structure 102 may be formed to include a vertically alternating (e.g., in the Z-direction) sequence of insulative material 104 and sacrificial material 106 arranged in tiers 108. Each of the tiers 108 of the preliminary stack structure 102 may individually include the sacrificial material 106 vertically neighboring (e.g., directly vertically adjacent) the insulative material 104. The preliminary stack structure 102 may include a lower section 130 and an upper section 132 overlying the lower section 130. The upper section 132 of the preliminary stack structure 102 may include a group of the tiers 108 that is relatively more distal from the base structure 110. The lower section 130 of the preliminary stack structure 102 may include an additional group of the tiers 108 that is relatively more proximate to the base structure 110.

The preliminary stack structure 102 may include the WL contact region 200, the extension/SGD contact region 300 horizontally adjacent to the WL contact region 200, and the optional transition region 450 horizontally between the WL contact region 200 and the extension/SGD contact region 300.

The WL contact region 200 may be formed to include at least one WL stadium structure 202. The WL stadium structure 202 may be formed within the horizonal area of the WL contact region 200 and vertically within the lower section 130 of the preliminary stack structure 102. The WL stadium structure 202 may be formed to include a forward staircase 204A, a reverse staircase 204B, or both. For example, the WL stadium structure 202 may be formed to include an opposing staircases 204 (a forward staircase 204A, a reverse staircase 204B) and a central region 205 horizontally interposed between (e.g., in the X-direction) the staircases. The WL stadium structure 202 includes steps 206 defined by edges (e.g., horizontal ends) of at least some of the tiers 108 of the lower section 130 of the preliminary stack structure 102. An individual step 206 may include a tread defined by a portion of an upper surface of a respective one of the tiers 108 of the lower section 130, and may also include a riser defined by a side surface the respective one of the tiers 108 of the lower section 130.

The extension/SGD contact region 300 may be formed to include at least one SGD stadium structure 302. The SGD stadium structure 302 may be formed within the horizonal area of the extension/SGD contact region 300 and vertically within the upper section 132 of the preliminary stack structure 102. The SGD stadium structure 302 may be formed to include a forward staircase, a reverse staircase, or both. For example, the SGD stadium structure 302 may be formed to include an opposing staircases 304 (a forward staircase 304A, a reverse staircase 304B) and a central area 305 horizontally interposed between (e.g., in the X-direction) the staircases. The staircases 304 of the SGD stadium structures 302 may respectively include steps 306 defined by edges (e.g., horizontal ends) of the tiers 108 of the preliminary stack structure 102.

As shown in FIG. 10, the implanted regions 210 may be formed within a horizontal area the WL stadium structure 202, and the implanted regions 310 may be formed within a horizontal area of the SGD stadium structure 302. For the WL stadium structure 202, the implanted regions 210 may be formed within portions of the sacrificial material 106 at selected steps 206 of the forward staircase 204A of the WL stadium structure 202. For the SGD stadium structure 302, the implanted regions 310 may be formed within portions of the sacrificial material 106 at selected steps 306 of the forward staircase 304A and at the central area 305 of the SGD stadium structure 302. For clarity and ease of understanding of the drawings and related description, FIG. 10 is shown as having the implanted regions 210 at the steps 206 of the forward staircase 204A of the WL stadium structure 202, and the implanted regions 310 at the steps 306 of the forward staircase 304A of the SGD stadium structure 302. However, the implanted regions 210 may be formed at any selected steps 206 of the forward staircase 204A, the reverse staircase 204B, and/or the central area of the WL stadium structure 202. Furthermore, the implanted regions 310 may be formed at any selected steps 306 of the forward staircase 304A, the reverse staircase 304B, and/or the central area 305 of the SGD stadium structure 302.

A first dielectric fill material 115 may be formed to overlie the preliminary stack structure 102, including the SGD stadium structures 302 in the extension/SGD contact region 300, and the WL stadium structures 202 in the WL contact region 200. An uppermost boundary of the first dielectric fill material 115 may vertically overlie (e.g., in the Z-direction) uppermost boundaries (e.g., an uppermost surface) of an uppermost tier 108 of the preliminary stack structure 102.

An arrangement of support pillars 144 may be formed in the preliminary stack structure 102 to provide support during fabrication processing. For example, the support pillars 144 may be formed in the extension/SGD contact region 300, the transition region 450, the WL contact region 200, and the array region (not shown). For clarity and ease of understanding the drawings and associated description, the support pillars 144 are omitted from the horizontal area of the forward staircases 204A of the WL stadium structure 202 in the WL contact region 200 of the microelectronic device structure 100. However, it will be understood that any desirable quantity and distribution of the support pillars 144 may be formed within the microelectronic device structure 100.

The support pillars 144 may individually be formed to extend vertically from or proximate an upper boundary of the first dielectric fill material 115, through the preliminary stack structure 102, and to or beyond a lower boundary of the preliminary stack structure 102. At least some of the support pillars 144 may be configured and positioned to facilitate support of the insulative material 104 of each of the tiers 108 of the preliminary stack structure 102 during subsequent removal of the sacrificial material 106 of the tiers 108, as described in further detail below. In some embodiments, the support pillars 144 are configured to be electrically non-operable, such that the support pillars 144 may not directly physically connect to other electrically operable, conductive components of the device. In addition, an arrangement of deep contact structures 455 including conductive material may be formed in the transition region 450 of the preliminary stack structure 102.

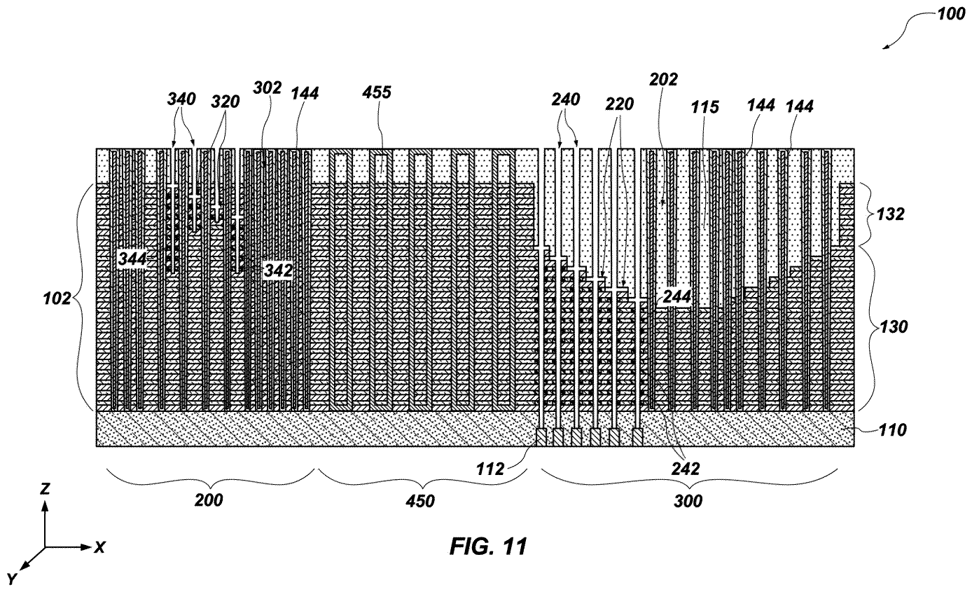

Referring next to FIG. 11, WL contact openings 240 may be formed within a horizontal area of the WL stadium structure 202 to extend from an upper surface of the first dielectric fill material 115 through an entire vertical extent (e.g., a height) of the preliminary stack structure 102 and to the conductive structures 112. Portions of the first dielectric fill material 115, the implanted regions 210, as well as the insulative material 104 and the sacrificial material 106 of the preliminary stack structure 102 may be removed by exposing the respective materials to wet etch chemistries and/or dry etch chemistries, for example, in one or more material removal processes. Thereafter, lateral portions of the sacrificial material 106 proximate the WL contact openings 240 may be converted to liner material 242. For example, the lateral portions of the sacrificial material 106 (e.g., a silicon nitride material) proximate to the WL contact openings 240 may be oxidized to form a liner material 242 (e.g., an oxide material having a material composition that differs from that of the remaining portions of the sacrificial material 106). The liner materials 242 may form isolation regions 244 between the WL contact openings 240 and the remaining portions of the horizontally neighboring sacrificial material 106. The remaining portions of the material of the implanted regions 210 (FIG. 10) may, optionally, be selectively removed (e.g., exhumed) to form lateral openings 220 in communication with (e.g., continuous with) the WL contact openings 240.

Further, SGD contact openings 340 may be formed within a horizontal area of the extension/SGD contact region 300 to extend vertically from an upper surface of the first dielectric fill material 115, through the implanted regions 310, and to tiers 108 of the preliminary stack structure 102 underlying the implanted regions 310. The SGD contact openings 340 may terminate at different tiers 108 of the preliminary stack structure 102 underlying the implanted regions 310. Some of the SGD contact openings 340 may terminate at the tiers 108 within the upper section 132 of the preliminary stack structure 102. Some of the SGD contact openings 340 may terminate at the tiers 108 within the lower section 130 of the stack structure. Portions of the first dielectric fill material 115, the implanted regions 310, as well as the insulative material 104 and the sacrificial material 106 of the preliminary stack structure 102 may be removed by exposing the respective materials to wet etch chemistries and/or dry etch chemistries, for example, in one or more material removal processes.

Lateral portions of the sacrificial material 106 proximate to the SGD contact openings 340 may be converted (e.g., oxidized) to a liner material 342 having a different material composition from that of the remaining portions of the sacrificial material 106. The liner materials 342 may form isolation regions 344 between the SGD contact openings 340 and the remaining portions of the horizontally neighboring sacrificial material 106. The remaining portions of the material of the implanted regions 310 (FIG. 10) may, optionally, be selectively removed (e.g., exhumed) to form lateral openings 320 in communication with (e.g., continuous with) the SGD contact openings 340.

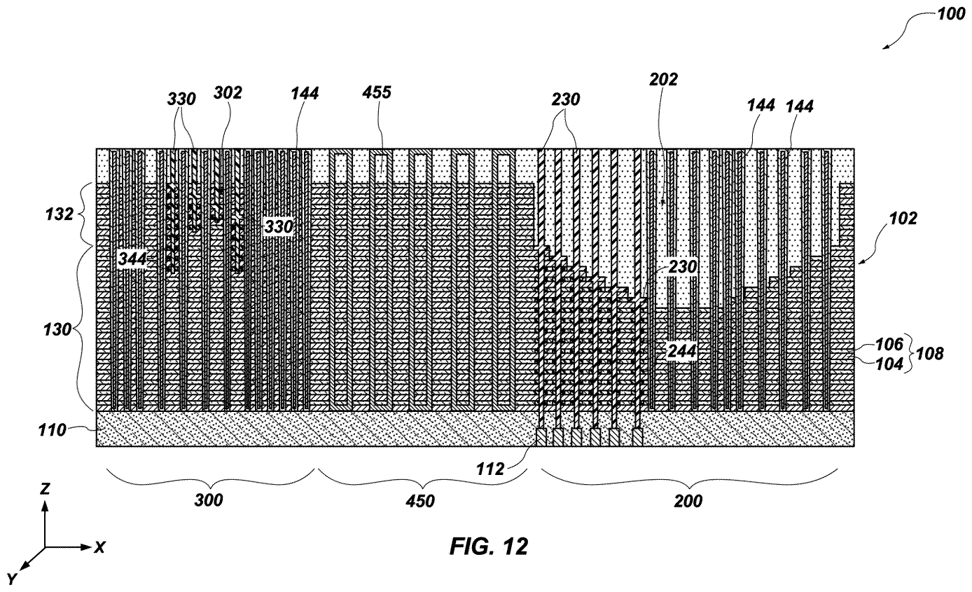

Referring next to FIG. 12, a first sacrificial fill material 230 may, optionally, be formed within one or more of the WL contact openings 240 (FIG. 11) and the lateral openings 220 (FIG. 11). The first sacrificial material fill material 230 may be formed within the WL contact openings 240 (FIG. 11) to be substantially continuous along a vertical dimension of the preliminary stack structure 102, as well as within the lateral openings 220 (FIG. 11) to be substantially continuous along a horizontal dimension of the selected steps 206 of the WL stadium structure 202. The first sacrificial fill material 230 may extend from the upper surface of the first dielectric fill material 115 through the preliminary stack structure 102 and to the conductive structures 112 underlying the preliminary stack structure 102. The first sacrificial fill material 230 may be configured and positioned to protect the materials (e.g., the first dielectric fill material 115, the insulative material 104, the liner material 242 of the isolation regions 244, the conductive structures 112) defining the WL contact openings 240 (FIG. 11) and the lateral openings 220 (FIG. 11) from being removed during the subsequent material removal processes of the preliminary stack structure 102 (e.g., replacement gate processing acts).

A second sacrificial fill material 330 may, optionally, be formed within one or more of the SGD contact openings 340 (FIG. 11) and the lateral openings 320 (FIG. 11). The second sacrificial fill material 330 may be formed within the SGD contact openings 340 (FIG. 11) to be substantially continuous along a vertical dimension of the preliminary stack structure 102, as well as within the lateral openings 320 (FIG. 11) to be substantially continuous along a horizontal dimension of the selected steps 306 of the SGD stadium structure 302. The second sacrificial fill material 330 may be configured and positioned to protect the materials (e.g., the first dielectric fill material 115, the insulative material 104, and the liner material of the isolation regions 344) defining the SGD contact openings 340 (FIG. 11) and the lateral openings 320 (FIG. 11) from being removed during the subsequent material removal processes of the preliminary stack structure 102 (e.g., replacement gate processing acts). The material of the second sacrificial fill material 330 may be the same as that of the first sacrificial fill material 230, or the material of the second sacrificial fill material 330 may be different from that of the first sacrificial fill material 230. In some embodiments, the second sacrificial fill material 330 includes one or more of the materials described above with reference to the sacrificial material 106 (e.g., Si₃N₄). In other embodiments, the second sacrificial fill material 330 includes one or more of conductive material and semiconductive material.

The first sacrificial fill material 230 may be formed within the WL contact openings 240 (FIG. 11) at the same processing step that the second sacrificial fill material 330 is formed within the SGD contact openings 340 (FIG. 11), or at a different processing step than the second sacrificial fill material 330 is formed within the SGD contact openings 340 (FIG. 11). In some instances, voids (e.g., gaps, seams) are formed within the first sacrificial fill material 230 and/or second sacrificial fill material 330.

Following formation of the first sacrificial fill material 230 and the second sacrificial fill material 330, the microelectronic device structure 100 may, optionally, be subjected to a chemical mechanical planarization (CMP) process to remove material (e.g., additional portions of the first sacrificial fill material 230 and the second sacrificial fill material 330) overlying the preliminary stack structure 102.

Alternatively, the first sacrificial fill material 230 and the second sacrificial fill material 330 may not be formed at the processing stage of FIG. 12, such that the WL contact openings 240 and the associated lateral openings 220, as well as the SGD contact openings 340 and the associated lateral openings 320, may remain open during the subsequent processing acts (e.g., replacement gate processing acts).

Referring next to FIG. 13, which is a simplified, partial top-down view of the microelectronic device structure 100 following the processing stage previously described with reference to FIG. 12, slots 151 (e.g., slits, openings) may be formed to extend vertically (e.g., in the Z-direction) through an entire height of the preliminary stack structure 102 and extend horizontally (e.g., in the X-direction) through the extension/SGD contact region 300 and the WL contact region 200 of the preliminary stack structure 102. For example, slots 151 may extend vertically through the first dielectric fill material 115 (FIG. 12) of the WL contact region 200 and the extension/SGD contact region 300, as well as the insulative material 104 and the sacrificial material 106 of the preliminary stack structure 102 (FIG. 12). The slots 151 may also horizontally extend (e.g., in the X-direction) through a memory array region of the preliminary stack structure 102 configured to contain vertically extending strings of memory cells (e.g., vertically extending strings of non-volatile memory cells, such as vertically extending strings of charge-trapping memory cells and/or vertically extending strings of floating gate memory cells).

While the slots 151 are illustrated herein as being formed after formation of the first sacrificial fill material 230 and the second sacrificial fill material 330, it is understood that the slots 151 may, alternatively, be formed before formation of the first sacrificial fill material 230 and the second sacrificial fill material 330. Furthermore, the slots 151 may be formed during (e.g., substantially simultaneously with) the formation of the WL contact openings 240 and/or the formation of the SGD contact openings 340.

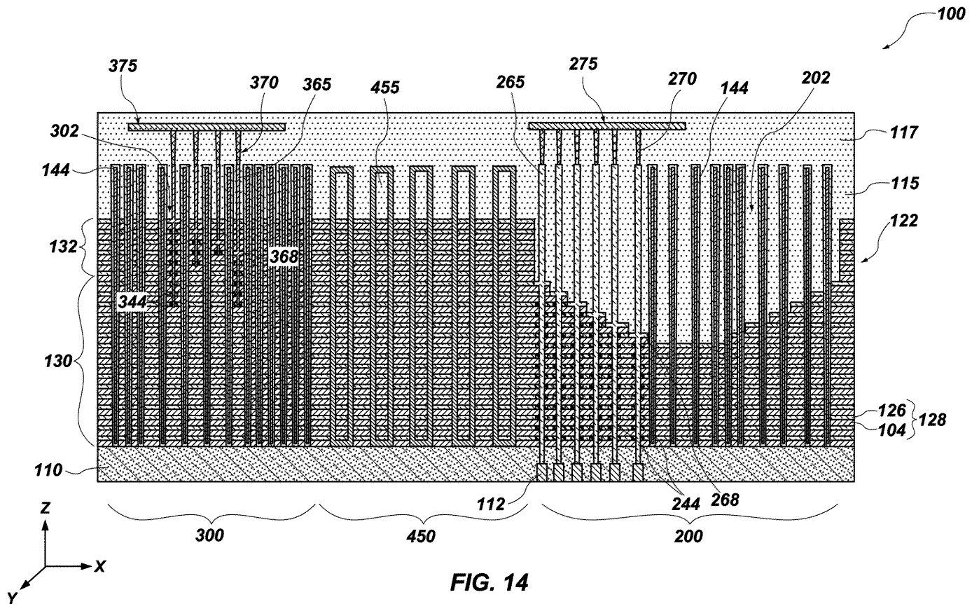

Referring next to FIG. 14, which is the microelectronic device structure 100 following the processing stage previously described with reference to FIGS. 12 and 13, the sacrificial material 106 (FIG. 12) of the tiers 108 (FIG. 12) of the preliminary stack structure 102 (FIG. 12) may be replaced with conductive material 126 through a replacement gate process.

The sacrificial material 106 (FIG. 12) of the tiers 108 (FIG. 12) of the preliminary stack structure 102 (FIG. 12) may be selectively removed (e.g., exhumed) through the slots 151 (FIG. 13). The sacrificial material 106 of the tiers 108 of the preliminary stack structure 102 may be at least partially (e.g., substantially) replaced with conductive material 126 to form a stack structure 122 comprising tiers 128 vertically stack relative to one another and respectively including a level of the conductive material 126 vertically neighboring a level of the insulative material 104. Optionally, at least one liner material (e.g., at least one insulative liner material, at least one conductive liner materials) may be formed around the conductive material 126 of one or more tiers 128 of the stack structure 122. The liner material may, for example, be formed of and include one or more a metal, an alloy, a metal nitride, and a metal oxide. In some embodiments, the liner material comprises at least one conductive material employed as a seed material for the formation of the conductive material 126. In some embodiments, the liner material further includes high-K dielectric material.

The first sacrificial fill material 230 (FIG. 12) of the WL contact region 200 and the second sacrificial fill material 330 (FIG. 12) of the extension/SGD contact region 300 may be selectively removed (e.g., exhumed) through the slots 151 (FIG. 13) (e.g., through the processing acts of the replacement gate process, the processing acts preceding the replacement gate process, or processing acts followed the replacement gate process). For example, the first sacrificial fill material 230 and the second sacrificial fill material 330 may be removed during (e.g., substantially simultaneous with) removal of the sacrificial material 106 (FIG. 12) of the tiers 108 (FIG. 12) of the preliminary stack structures 102 (FIG. 12). In embodiments wherein the implanted regions 210 (FIG. 10) remain within a horizontal area of the WL stadium structure 202 and the implanted regions 310 (FIG. 10) remain within a horizontal area of the SGD stadium structure 302, the remaining portions of the implanted regions 210 and the implanted regions 310 may be selectively removed (e.g., exhumed) through the cell openings between the insulative material 104 during (e.g., substantially simultaneous with) removal of the sacrificial material 106 (FIG. 12) and/or removal of the first sacrificial fill material 230 (FIG. 12) and the second sacrificial fill material 330 (FIG. 12).

After the removal of the first sacrificial fill material 230 (FIG. 12) of the WL contact region 200, the resulting WL openings may be substantially filled with a conductive material to form the conductive contacts 265. Once formed, each of the conductive contacts 265 may extend vertically (e.g., in the Z-direction) completely through the stack structure 122 and to the conductive structures 112 in the base structure 110. During the formation of the conductive contacts 265, the conductive fill material thereof may also substantially fill the lateral openings 220 (FIG. 12) to form the strapping structures 268. The conductive contacts 265 may be integral and continuous (e.g., unitary) with the strapping structures 268. As shown in FIG. 14, for an individual conductive contact 265, a group of the isolation regions 244 may electrically isolate the conductive contact 265 from the conductive material 126 of tiers 128 vertically underlying the strapping structure 268 operatively associated (e.g., unitary) with the conductive contact 265.

In addition, after removing the second sacrificial fill material 330 (FIG. 12) and the lateral openings 320 (FIG. 12) from the extension/SGD contact region 300, the resulting SGD openings may be substantially filled with conductive fill material to form the additional conductive contacts 365. A material composition of the additional conductive contacts 365 may be the same as that of the conductive contacts 265, or the material composition of the additional conductive contacts 365 may be different from that of the conductive contacts 265. Once formed, each of the additional conductive contacts 365 may extend vertically (e.g., in the Z-direction) into the tiers 128 of stack structure 122 defining the SGD stadium structures 302. During the formation of the additional conductive contacts 365, the conductive fill material thereof may also substantially fill the lateral openings 320 (FIG. 12) to form the strapping structures 368. The additional conductive contacts 365 may be integral and continuous (e.g., unitary) with the strapping structures 368. For an individual additional conductive contact 365, an additional group of the isolation regions 344 may electrically isolate the additional conductive contact 365 from the conductive material 126 of tiers 128 vertically underlying the strapping structure 368 operatively associated (e.g., unitary) with the additional conductive contact 365.

Thereafter, further processing acts similar to those previously described with reference to FIGS. 9A and 9B may be performed, followed by formation of a second dielectric fill material 117 over the first dielectric fill material 115. A material composition of the second dielectric fill material 117 may be substantially the same as the material composition of the first dielectric fill material 115, or the material composition of the second dielectric fill material 117 may be different from the material composition of the first dielectric fill material 115. In some embodiments, the second dielectric fill material 117 is formed of and includes SiOₓ (e.g., SiO₂).

Interconnect structures 270 may be formed to vertically extend through the second dielectric fill material 117 to the conductive contacts 265. The interconnect structures 270 may individually be over (e.g., directly on) and in electrical contact with a respective one of the conductive contacts 265. In addition, additional conductive routing structures 275 may be formed over (e.g., directly on) and in electrical contact with the interconnect structures 270. The interconnect structures 270 may individually be coupled to and vertically intervene between a respective one of the conductive contacts 265 and a respective one of the additional conductive routing structures 275.

Additional interconnect structures 370 may be formed to vertically extend through the second dielectric fill material 117 to the additional conductive contacts 365. A material composition of the additional interconnect structures 370 may be substantially the same as a material composition of the interconnect structures 270, or a material composition of the additional interconnect structures 370 may be different from a material composition of the interconnect structures 270. The additional interconnect structures 370 may individually be over (e.g., directly on) and in electrical contact with a respective one of the additional conductive contacts 365. The conductive routing structures 375 may be formed over (e.g., directly on) and in electrical contact with the additional interconnect structures 370. The additional interconnect structures 370 may individually be coupled to and vertically intervene between a respective one of the additional conductive contacts 365 and a respective one of the conductive routing structures 375.

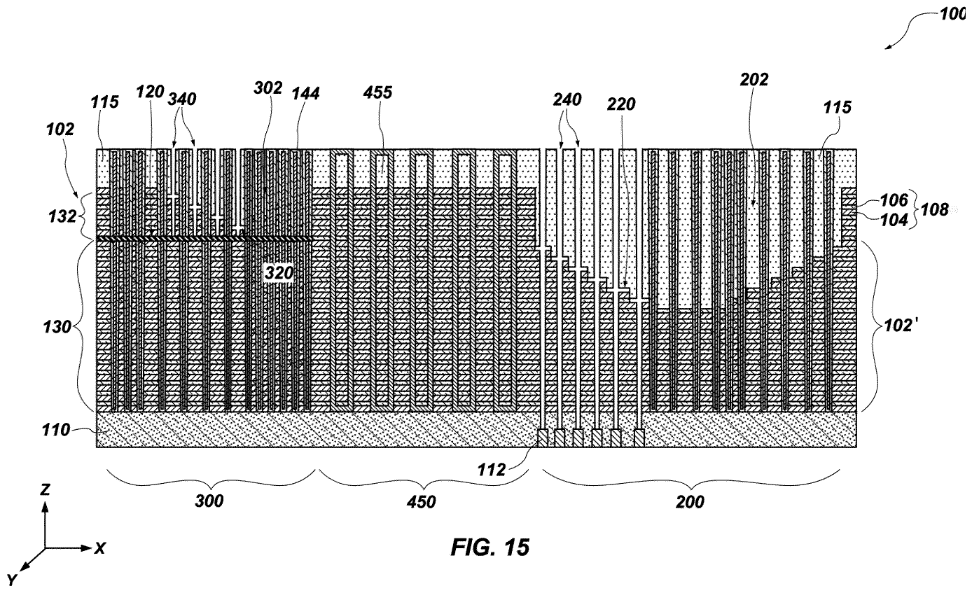

FIGS. 15 through 17 are simplified partial cross-sectional views illustrating different processing stages of a method of forming a microelectronic device (e.g., a memory device such as a 3D NAND Flash memory device), in accordance with yet further embodiments of the disclosure. With the description provided below, it will be readily apparent to one of ordinary skill in the art that the methods and structures described herein with reference to FIGS. 15 through 17 may be used in the formation and configuration of various devices and electronic systems. In other words, the methods of the disclosure may be used whenever it is desired to form a microelectronic device.

Referring to FIG. 15, a method for forming a microelectronic device structure according to some further embodiments may include forming an initial stack structure 102′ over a base structure 110 comprising conductive structures 112 (e.g., conductive routing structures, conductive line structures). The initial stack structure 102′ may be formed to include a vertically alternating (e.g., in the Z-direction) sequence of insulative material 104 and sacrificial material 106 arranged in tiers 108. Each of the tiers 108 of the preliminary stack structure 102 may individually include the sacrificial material 106 vertically neighboring (e.g., directly vertically adjacent) the insulative material 104. The initial stack structure 102′ may include the WL contact region 200, the extension/SGD contact region 300 horizontally adjacent to the WL contact region 200, and the optional transition region 450 horizontally between the WL contact region 200 and the extension/SGD contact region 300.

Within the extension/SGD contact region 300, an etch stop structure 120 may be formed to overlie a vertically uppermost one of the tiers 108 of the initial stack structure 102′. The WL contact region 200 and the transition region 450 may be free of the etch stop structure 120. The WL contact region 200 and the transition region 450 may be protected (e.g., masked) during the formation of the etch stop structure 120 on the initial stack structure 102′. Non-limiting examples of materials that may be included in the etch stop structure 120 include aluminum oxide (AlOₓ), aluminum oxycarbide (AlOC), aluminum oxynitride (AlON), silicon carbide, silicon carbonitride, or the like.

Thereafter, additional tiers of the insulative material 104 and the sacrificial material 106 may be formed overlying the initial stack structure 102′, resulting in a preliminary stack structure 102 having a higher number of the tiers 108 as compared to the initial stack structure 102′. The preliminary stack structure 102 may include a lower section 130 (i.e., the initial stack structure 102′), an upper section 132 overlying the lower section 130, and the etch stop structure 120 positioned vertically between the lower section 130 and the upper section 132. In some embodiments, the upper section 132 of the preliminary stack structure 102 is formed to include greater than or equal to four (4) of the tiers 108, such as greater than or equal to six (6) of the tiers 108, greater than or equal to eight (8) of the tiers 108, or greater than or equal to sixteen (16) of the tiers 108. In some embodiments, the lower section 130 of the preliminary stack structure 102 is formed to include a greater quantity of the tiers 108 than the subsequently formed upper section 132 of the preliminary stack structure 102.

The first dielectric fill material 115 may be formed over the SGD stadium structures 302 in the extension/SGD contact region 300 and over the WL stadium structures 202 in the WL contact region 200. The uppermost boundaries (e.g., uppermost surfaces) of the first dielectric fill material 115 in the WL contact region 200 and the extension/SGD contact region 300 may be formed to be substantially coplanar with an uppermost boundary (e.g., an uppermost surface) of the upper section 132 of the preliminary stack structure 102.

An arrangement of support pillars 144 may be formed in the preliminary stack structure 102 to provide support for the microelectronic device structure 100 during fabrication process. The support pillars 144 may individually be formed to extend vertically from an upper boundary of the first dielectric fill material 115, through the preliminary stack structure 102, and to or beyond a lower boundary of the preliminary stack structure 102. Any desirable quantity and distribution of the support pillars 144 may be formed within the microelectronic device structure 100. In some embodiments, the support pillars 144 may be configured to be electrically non-operable, such that the support pillars 144 may not directly physically connect to other electrically operable, conductive components of the device. In addition, an arrangement of deep contact structures 455 including conductive material may be formed in the transition region 450 of the preliminary stack structure 102.

The implanted regions may be formed within the WL stadium structure 202, and the implanted regions 310 may be formed within the SGD stadium structure 302 as described earlier in FIG. 10.

As described earlier with reference to FIG. 11, the WL contact openings 240 may be formed within a horizontal area of the WL stadium structure 202 to extend from an upper surface of the first dielectric fill material 115 through an entire vertical extent (e.g., a height) of the preliminary stack structure 102 and to the conductive structures 112. The remaining portions of the material of the implanted regions within the horizontal area of the WL stadium structure 202 may, optionally, be selectively removed to form lateral openings 220 in continuous with the WL contact openings 240. Further, SGD contact openings 340 may be formed within the horizontal area of the extension/SGD contact region 300 to extend vertically from an upper surface of the first dielectric fill material 115, through the implanted regions of the SGD stadium structure 302, and to the etch stop structure 120. Accordingly, a height of each of the SGD contact openings 340 in the vertical direction (e.g., the Z-direction) may be substantially similar to (e.g., substantially the same as) one another irrespective of horizontal orientation relative to the steps 306 of the SGD stadium structure 302. Manufacturing processes may be simplified by forming all WL contact openings 240 to extend vertically into the stack structure at the same depth (e.g., height in the Z-direction) and all SGD contact openings 340 to extend vertically into the stack structure at the same depth (e.g., height in the Z-direction). The remaining portions of the material of the implanted regions in the SGD stadium structure 302 may, optionally, be selectively removed to form lateral openings 320 in continuous with the SGD contact openings 340.

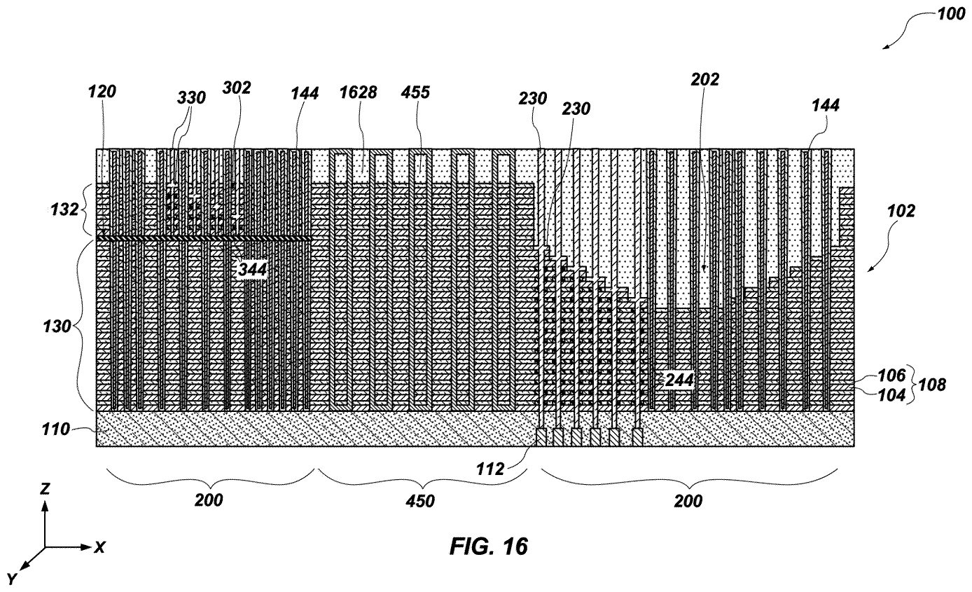

Referring next to FIG. 16, the lateral portions of the sacrificial material 106 proximate to the WL contact opening 240 may be converted to liner material, as previously described herein with reference to FIG. 7B, to create isolation regions 244 between the WL contact openings 240 and the remaining portions of the sacrificial material 106 of the tiers 108 of the preliminary stack structure 102. In addition, the lateral portions of the sacrificial material 106 of the tiers 108 proximate to the SGD contact opening 340 may be converted to liner material, as previously described herein with reference to FIG. 7B, to create isolation regions 344 between the SGD contact openings 340 and the remaining portions of the sacrificial material 106 of the tiers 108 of the preliminary stack structure 102.

The first sacrificial fill material 230 may, optionally, be formed within one or more of the WL contact openings 240 (FIG. 15) and the lateral openings 220 (FIG. 15) to protect the materials defining the WL contact openings 240 and the lateral openings 220 from being removed during the subsequent material removal processes of the preliminary stack structure 102 (e.g., replacement gate processing acts). The second sacrificial fill material 330 may, optionally, be formed within one or more of the SGD contact openings 340 and the lateral openings 320 to protect the materials defining the SGD contact openings 340 and the lateral openings 320 from being removed during the subsequent material removal processes of the preliminary stack structure 102 (e.g., replacement gate processing acts). Alternatively, the first sacrificial fill material 230 and/or the second sacrificial fill material 330 may not be formed at the processing stage of FIG. 16, such that the WL contact openings 240 and the associated lateral openings 220, as well as the SGD contact openings 340 and the associated lateral openings 320, may remain open during the subsequent processing acts (e.g., replacement gate processing acts).

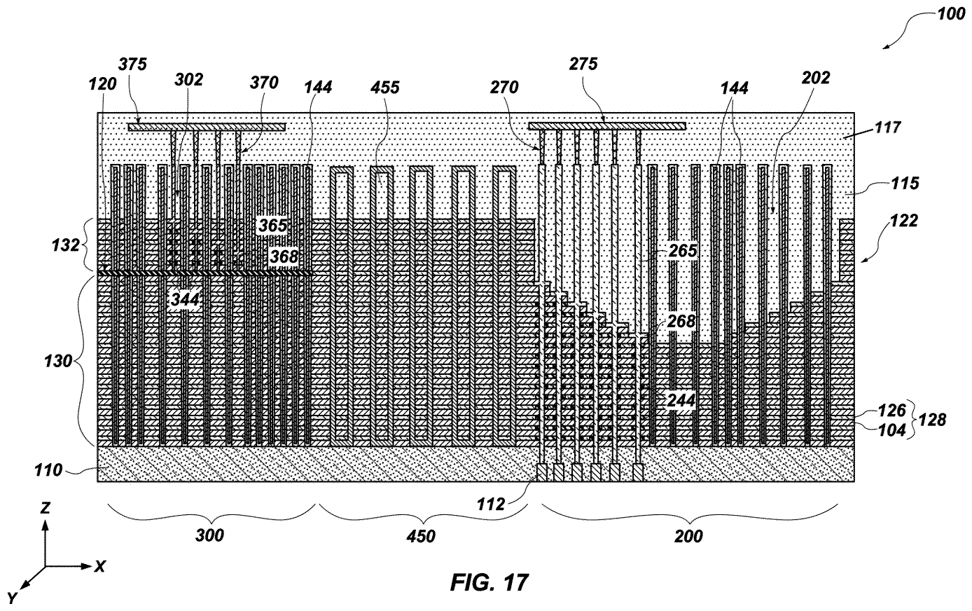

Referring to FIG. 17, the slots (corresponding to the slots 151 previously described herein with reference to FIG. 6) may be formed to extend vertically (e.g., in the Z-direction) through an entire height of the preliminary stack structure 102 and horizontally extend (e.g., in the X-direction) through the extension/SGD contact region 300 and the WL contact region 200. The slots may also horizontally extend (e.g., in the X-direction) through a memory array region of the preliminary stack structure 102 configured to contain vertically extending strings of memory cells (e.g., vertically extending strings of non-volatile memory cells, such as vertically extending strings of charge-trapping memory cells and/or vertically extending strings of floating gate memory cells). Then, a replacement gate process may be performed to replace the sacrificial material 106 (FIG. 16) of the tiers 108 (FIG. 16) of the preliminary stack structure 102 (FIG. 16) with conductive material 126 through the replacement gate slots to form the stack structure 122. The first sacrificial fill material 230 (FIG. 16) and the second sacrificial fill material 330 (FIG. 16) may also be removed during the replacement gate process. After the removal of the first sacrificial fill material 230 (FIG. 16), the resulting WL openings and lateral openings may be substantially filled with conductive material to form the conductive contacts 265 integral and continuous (e.g., unitary) with the strapping structures 268. As shown in FIG. 17, for an individual conductive contact 265, the isolation regions 244 may electrically isolate the conductive contact 265 from the conductive material 126 of a group of the tiers 128 vertically underlying the strapping structure 268 operatively associated (e.g., unitary) with the conductive contact 265. After removing the second sacrificial fill material 330 (FIG. 16), the resulting SGD openings and lateral openings may be substantially filled with conductive material to form the additional conductive contacts 365 integral and continuous (e.g., unitary) with the strapping structures 368. For an individual additional conductive contact 365, the isolation regions 344 may electrically isolate the additional conductive contacts 365 from the conductive material 126 of an additional group of the tiers 128 vertically underlying the strapping structure 368 operatively associated (e.g., unitary) with the additional conductive contact 365.

After the replacement gate process, the replacement gate slots may be at least partially filled with dielectric material to form first dielectric-filled slot structures segmenting the stack structure 122 into blocks. In addition, within an individual block, second dielectric-filled slot structures may be formed to segment the block into sub-blocks.

Interconnect structures 270 may be formed to vertically extend through the second dielectric fill material 117 to the conductive contacts 265. The interconnect structures 270 may individually be over (e.g., directly on) and in electrical contact with a respective one of the conductive contacts 265. In addition, additional conductive routing structures 275 may be formed over (e.g., directly on) and in electrical contact with the interconnect structures 270. The interconnect structures 270 may individually be coupled to and vertically intervene between a respective one of the conductive contacts 265 and a respective one of the additional conductive routing structures 275.

Additional interconnect structures 370 may be formed to vertically extend through the second dielectric fill material 117 to the additional conductive contacts 365. A material composition of the additional interconnect structures 370 may be substantially the same as a material composition of the interconnect structures 270, or a material composition of the additional interconnect structures 370 may be different from a material composition of the interconnect structures 270. The additional interconnect structures 370 may individually be over (e.g., directly on) and in electrical contact with a respective one of the additional conductive contacts 365. The conductive routing structures 375 may be formed over (e.g., directly on) and in electrical contact with the additional interconnect structures 370. The additional interconnect structures 370 may individually be coupled to and vertically intervene between a respective one of the additional conductive contacts 365 and a respective one of the conductive routing structures 375.

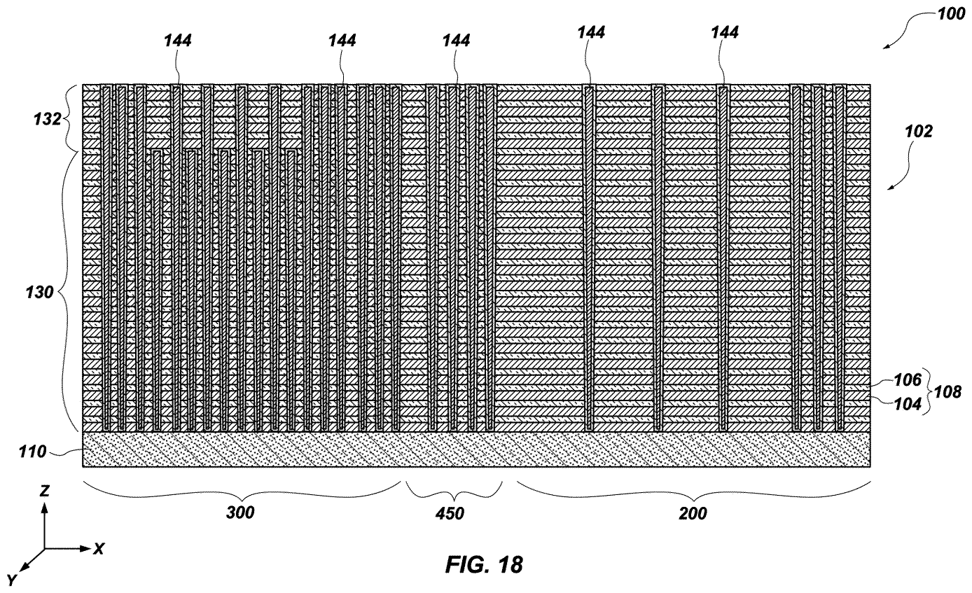

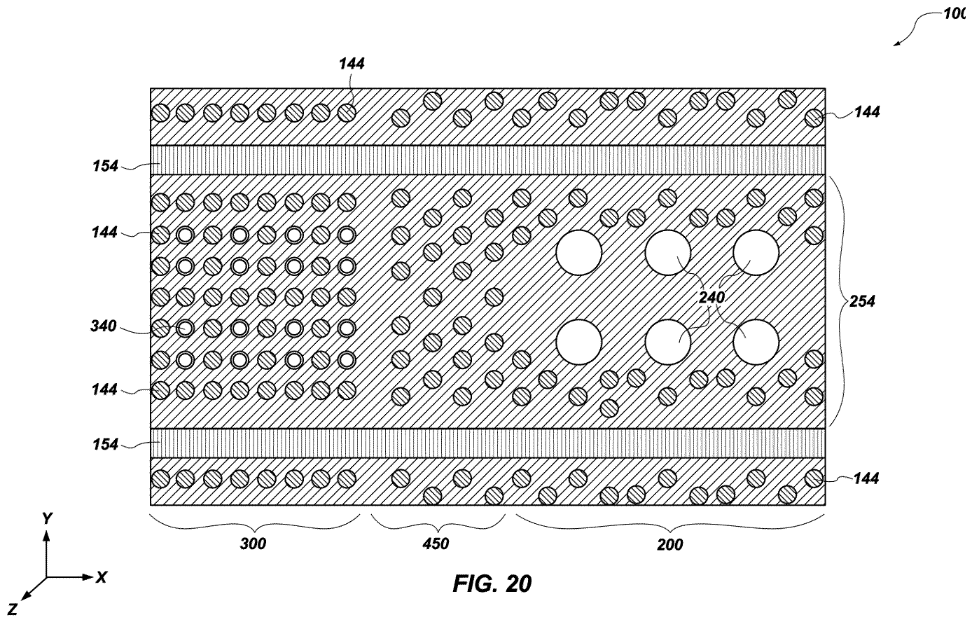

FIGS. 18 through 25B are simplified, partial cross-sectional views (FIGS. 18, 19, 21, 22B, 23B, 24 and 25B) and simplified, partial top-down views (FIGS. 20, 22A, 23A and 25A) illustrating different processing stages of a method of forming a microelectronic device (e.g., a memory device such as a 3D NAND Flash memory device), in accordance with yet still further embodiments of the disclosure. With the description provided below, it will be readily apparent to one of ordinary skill in the art that the methods and structures described herein with reference to FIGS. 18 through 25B may be used in the formation and configuration of various devices and electronic systems. In other words, the methods of the disclosure may be used whenever it is desired to form a microelectronic device.

Referring to FIG. 18, a method for forming a microelectronic device according to additional embodiments includes forming a preliminary stack structure 102 over a base structure 110 comprising conductive structures 112 (e.g., conductive routing structures, conductive line structures). The preliminary stack structure 102 may be formed to include a vertically alternating (e.g., in the Z-direction) sequence of insulative material 104 and sacrificial material 106 arranged in tiers 108. Each of the tiers 108 of the preliminary stack structure 102 may individually include the sacrificial material 106 vertically neighboring (e.g., directly vertically adjacent) the insulative material 104. The preliminary stack structure 102 may include a lower section 130 and an upper section 132 overlying the lower section 130. The upper section 132 of the preliminary stack structure 102 may include a group of the tiers 108 that is relatively more distal from the base structure 110. The lower section 130 of the preliminary stack structure 102 may include an additional group of the tiers 108 that is relatively more proximate to the base structure 110. In some embodiments, the lower section 130 of the preliminary stack structure 102 includes a greater quantity of the tiers 108 than the upper section 132 of the preliminary stack structure 102. In some embodiments, the upper section 132 of the preliminary stack structure 102 is formed to include greater than or equal to four (4) of the tiers 108, such as greater than or equal to six (6) of the tiers 108, greater than or equal to eight (8) of the tiers 108, or greater than or equal to sixteen (16) of the tiers 108. The preliminary stack structure 102 may include the WL contact region 200, the extension/SGD contact region 300 horizontally adjacent to the WL contact region 200, and the optional transition region 450 horizontally between the WL contact region 200 and the extension/SGD contact region 300.

An arrangement of support pillars 144 may be formed at least in the WL contact region 200, the extension/SGD contact region 300, and the optional transition region 450 region of the preliminary stack structure 102 to provide support for the microelectronic device structure 100 during fabrication process. Some support pillars 144 may extend vertically through a whole height (e.g., in the Z-direction) of the preliminary stack structure 102. Some other support pillars 144 may extend vertically through the lower section 130 of the preliminary stack structure 102, but not the upper section 132 of the preliminary stack structure 102. Any desirable quantity and distribution of the support pillars 144 may be formed within the microelectronic device structure 100. In some embodiments, the support pillars 144 may be configured to be electrically non-operable, such that the support pillars 144 may not directly physically connect to other electrically operable, conductive components of the device.

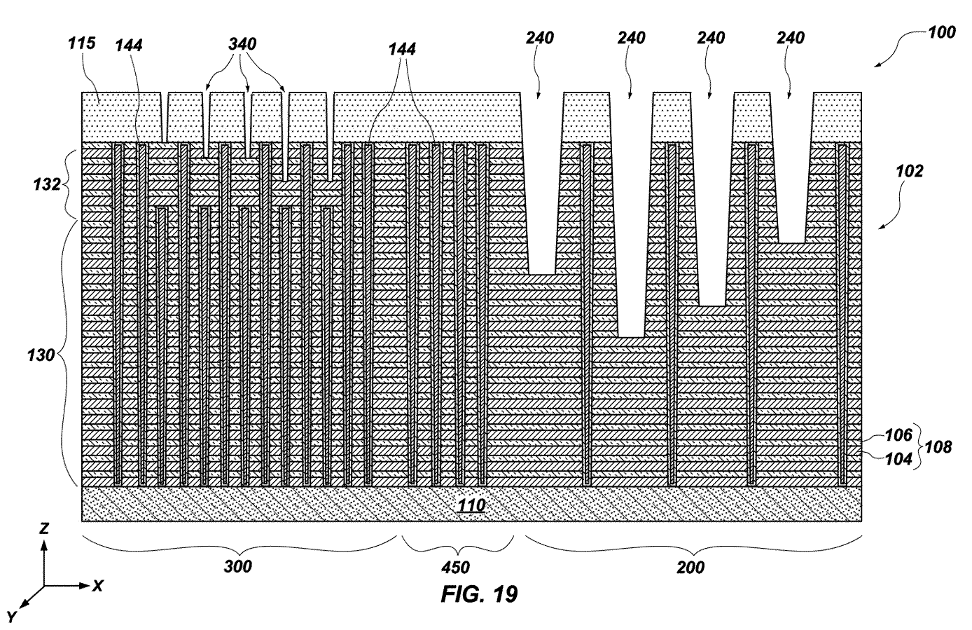

Referring collectively to FIGS. 19 and 20, which respectively illustrate a simplified, vertical cross-sectional view and a simplified, partial top-view of the microelectronic device structure 100 at a process stage following that previously described with reference to FIG. 18, a first dielectric fill material 115 may be formed over the preliminary stack structure 102. The preliminary stack structure 102 may then be patterned (e.g., etched, in one or more material removal processing acts) to form WL contact openings 240 within the WL contact region and SGD contact openings 340 within the extension/SGD contact region 300. The WL contact openings 240 may be formed at the same time (e.g., some processing acts) as the SGD contact openings 340, or the WL contact openings 240 may be formed before or after (e.g., different processing acts) the SGD contact openings 340. In some embodiments, WL contact openings 240 are formed at the same time (e.g., some processing acts) as the SGD contact openings 340.

Within the WL contact region 200, the WL contact openings 240 may be formed to extend substantially vertically through an upper portion of the preliminary stack structure 102 to terminate at various tiers 108 of the preliminary stack structure 102, such as various tiers 108 of the lower section 130 of the preliminary stack structure 102. Each WL contact opening 240 may be a discrete opening extending through some number of the tiers 108 of the preliminary stack structure 102, such that horizontal boundaries of the WL contact openings 240 may be defined by sidewalls of the materials of the tiers 108 of the preliminary stack structure 102. Each WL contact opening 240 may initially terminate at or in the insulative material 104 of a respective one of the tiers 108, such that bottom of the WL contact opening 240 expose a portion of the insulative material 104 of the respective one of the tiers 108.

Within the extension/SGD contact region 300, the SGD contact openings 340 may be formed to extend substantially vertically through an upper portion of the preliminary stack structure 102 to terminate at various additional tiers 108 of the upper section 132 of the preliminary stack structure 102. Each SGD contact opening 340 may be a discrete opening extending through some number of the tiers 108 of the upper section 132 of the preliminary stack structure 102, and initially terminates at or in the insulative material 104 of another respective one of the tiers 108 such that a bottom of the SGD contact opening 340 may expose a portion of the insulative material 104 of the another respective one of the tiers 108. Lower boundaries (e.g., bottoms) of each of the SGD contact openings 340 may vertically lower boundaries (e.g., bottoms) of each of the WL contact openings 240.

As shown in FIG. 20, the preliminary stack structure 102 may be patterned to form replacement gate slots that subsequently may be at least partially (e.g., substantially) filled with a sacrificial material to form a sacrificially filled slots 154. For example, the sacrificial fill material may be deposited within the replacement gate slots through a spin-on coating process. In some embodiments, the sacrificial fill material is a spin-on carbon. In some embodiments, the sacrificial fill material includes an oxide material (e.g., silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide); a nitride material (e.g., silicon nitride), an oxynitride material (e.g., silicon oxynitride), a dielectric carbon nitride material (e.g., silicon carbon nitride), a dielectric carboxynitride material (e.g., silicon carboxynitride), or combinations thereof. In some embodiments, the sacrificially filled slots 154 are respectively formed of and include SiOₓ (e.g., SiO₂). In additional embodiments, the sacrificially filled slots 154 are respectively formed of and include SiN_{y} (e.g., Si₃N₄).

The sacrificially filled slots 154 may be formed to extend vertically (e.g., in the Z-direction) through an entire height of the preliminary stack structure 102 and horizontally extend (e.g., in the X-direction) through the extension/SGD contact region 300 and the WL contact region 200 of the preliminary stack structure 102. The sacrificially filled slots 154 may also horizontally (e.g., in the X-direction) through a memory array region of the preliminary stack structure 102 configurated to contain vertically extending strings of memory cells (e.g., vertically extending strings of non-volatile memory cells, such as vertically extending strings of charge-trapping memory cells and/or vertically extending strings of floating gate memory cells). The sacrificially filled slots 154 divide the preliminary stack structure 102 into blocks 254. The blocks 254 may be formed to horizontally extend parallel in an X-direction and may be separated from one another in a Y-direction by the sacrificially filled slots 154. In some embodiments, the blocks 254 of the preliminary stack structure 102 are substantially uniformly (e.g., substantially non-variably, substantially equally, substantially consistently) sized, shaped, and spaced relative to one another.

In some embodiments, the replacement gate slots are formed during (e.g., substantially simultaneously with) the formation of the WL contact openings 240 and/or the formation of the SGD contact openings 340. In additional embodiments, the replacement gate slots are formed after the formation of the WL contact openings 240 and/or the formation of the SGD contact openings 340. In further embodiments, the replacement gate slots are formed before the formation of the WL contact openings 240 and/or the formation of the SGD contact openings 340.

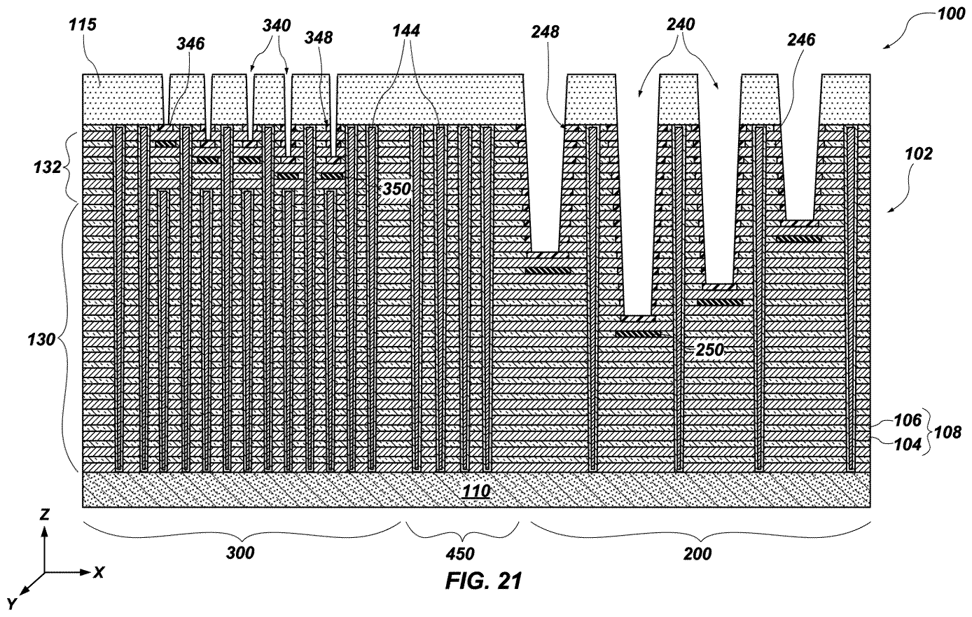

Referring next to FIG. 21, the microelectronic device structure 100 may be subjected to an etching process that selectively removes portions of the sacrificial material 106 of some of the tiers 108 of the preliminary stack structure 102 relative to the insulative material 104 of the some of the tiers 108 of the preliminary stack structure 102. For the WL contact region 200, portions of the sacrificial material 106 of respective ones of the tiers 108 exposed by the WL contact openings 240 may be selectively removed to form horizontal recesses 246 in the sacrificial material 106 of the respective ones of the tiers 108. For the extension/SGD contact region 300, portions of the sacrificial material 106 of additional respective ones of the tiers 108 exposed by the SGD contact openings 340 may be selectively removed to form horizontal recesses 346 in the sacrificial material 106 of the additional respective ones of the tiers 108. In some embodiments, the formation of the recess 246 depicted in in FIG. 21 is omitted, and sidewalls of the sacrificial material 106 of various tiers 108 exposed by the WL contact openings 240 and the SGD contact openings 340 substantially horizontally (e.g., in the X-direction) align with the exposed sidewalls of the vertically adjacent insulative material 104 of the various tiers 108 exposed by the WL contact openings 240.

Liner material 248 may be conformally formed in the WL contact openings 240 and the recesses 246 associated therewith. In addition, the liner material 348 may be conformally formed in the SGD contact openings 340 and the recesses 346 associated. The liner materials 248, 348 may be formed of and include dielectric material, such as dielectric oxide material (e.g., one or more of SiOₓ, AlOₓ, HfOₓ, NbOₓ, TiOₓ, ZrOₓ, and MgOₓ). A material composition of the liner material 248, 348 may be selected such that the sacrificial material 106 of the preliminary stack structure 102 may be selectively removed relative to the liner materials 248, 348.

Optionally, as shown in FIG. 21, the microelectronic device structure 100 may be subjected to a carbon ion implantation process prior to the formation of the liner materials 248, 348 in the WL contact openings 240 and the SGD contact openings 340 respectively, or alternatively after the formation of the liner materials 248, 348 in the WL contact openings 240 and the SGD contact openings 340 respectively. Carbon ions may be implanted into the sacrificial material 106 of the tiers 108 vertically underlying and most proximate to bottoms of the WL contact openings 240 to form carbon ion-implanted structures 250. Each of the carbon ion-implanted structures 250 vertically underlies (e.g., in the Z-direction) and at least partially (e.g., substantially) horizontally overlaps (e.g., in the X-direction, in the Y-direction) a respective one of the WL contact openings 240. In some embodiments, an individual carbon ion-implanted structure 250 vertically underlies and is substantially horizontally aligned (e.g., in the X-direction and in the Y-direction) a respective one of the WL contact openings 240. In addition, carbon ion may be implanted into the sacrificial material 106 of the tiers 108 vertically underlying and most proximate to bottoms of the SGD contact openings 340 to form additional carbon ion-implanted structures 350. Each of the additional carbon ion-implanted structures 350 vertically underlies (e.g., in the Z-direction) and at least partially (e.g., substantially) horizontally overlaps (e.g., in the X-direction, in the Y-direction) a respective one of the SGD contact openings 340. In some embodiments, an individual additional carbon ion-implanted structure 350 vertically underlies and is substantially horizontally aligned (e.g., in the X-direction and in the Y-direction) a respective one of the SGD contact openings 340.

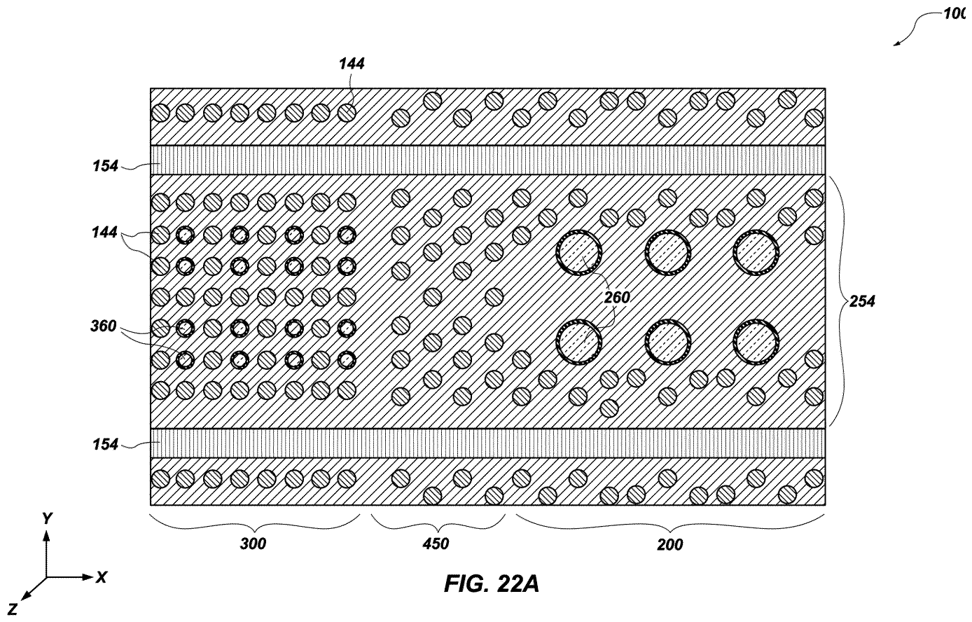

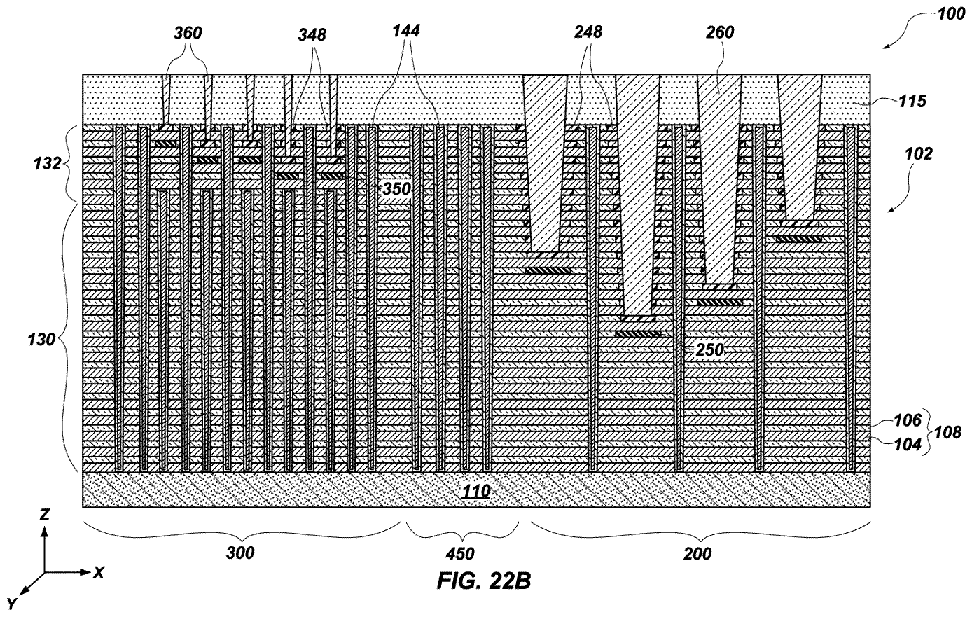

Referring collectively to FIGS. 22A and 22B, which respectively illustrate the simplified, partial top-down view and the simplified, vertical cross-sectional view of the microelectronic device structure 100 at a processing stage following that described with reference to FIGS. 20 and 21, the WL contact openings 240 (FIG. 21) and the SGD contact openings 340 (FIG. 21) may be substantially filled with a contact sacrificial fill material to form sacrificially filled the WL contact structures 260 and the sacrificially filled the SGD contact structures 360, respectively. A material composition of the contact sacrificial fill material may be selected such that the sacrificial material 106 of the preliminary stack structure 102 and the sacrificial fill material of the sacrificially filled slots 154 may be selectively removed (e.g., selectively etchable) relative to the contact sacrificial fill material.

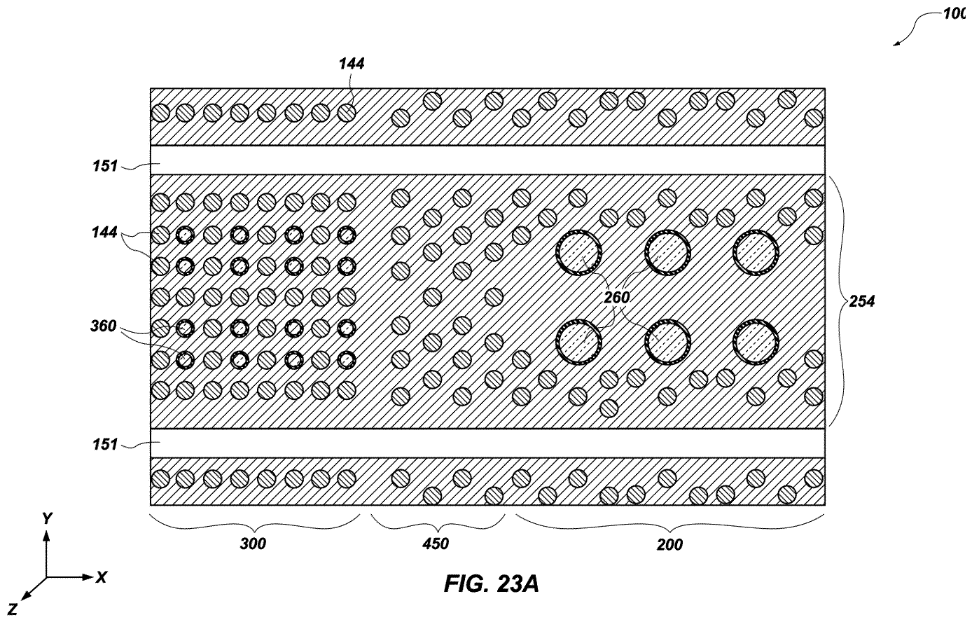

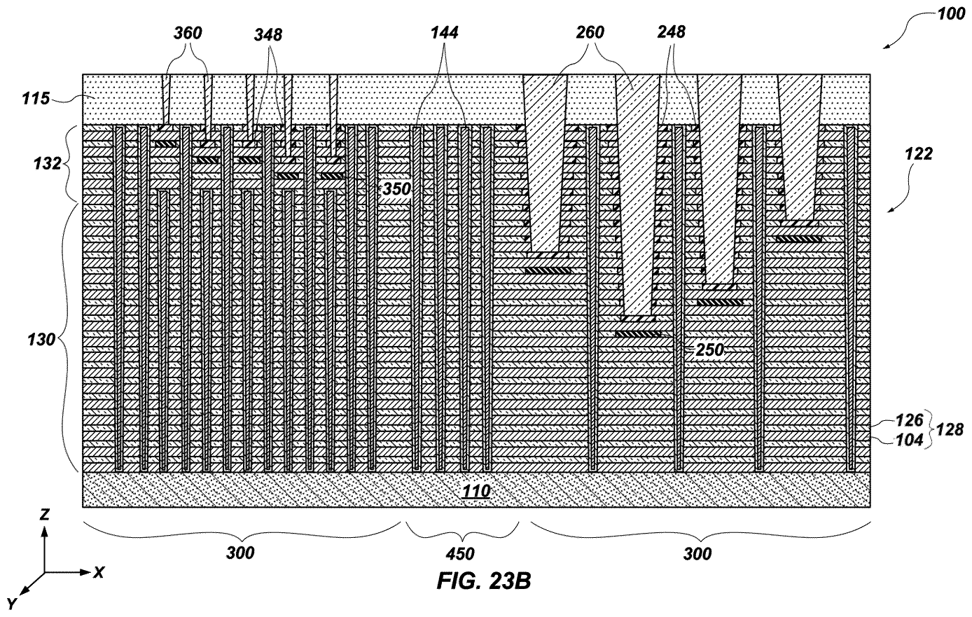

Referring next collectively to FIGS. 23A and 23B, the sacrificial fill material of the sacrificially filled slots 154 (FIG. 22A) may be removed to form the slots 151 for the replacement gate process. During the gate replacement process, the sacrificial material 106 (FIG. 22B) of the tiers 108 (FIG. 22B) of the preliminary stack structure 102 (FIG. 22B) may be replaced with conductive material 126 by way of the slots 151, to form a stack structure 122 comprising tiers 208 vertically stacked relative to one another and respectively including a level of the conductive material 126 vertically neighboring a level of the insulative material 104. Optionally, at least one liner material (e.g., at least one insulative liner material, at least one conductive liner materials) may be formed around the conductive material 126 of one or more (e.g., each) of the tiers 208 of the stack structure 122.

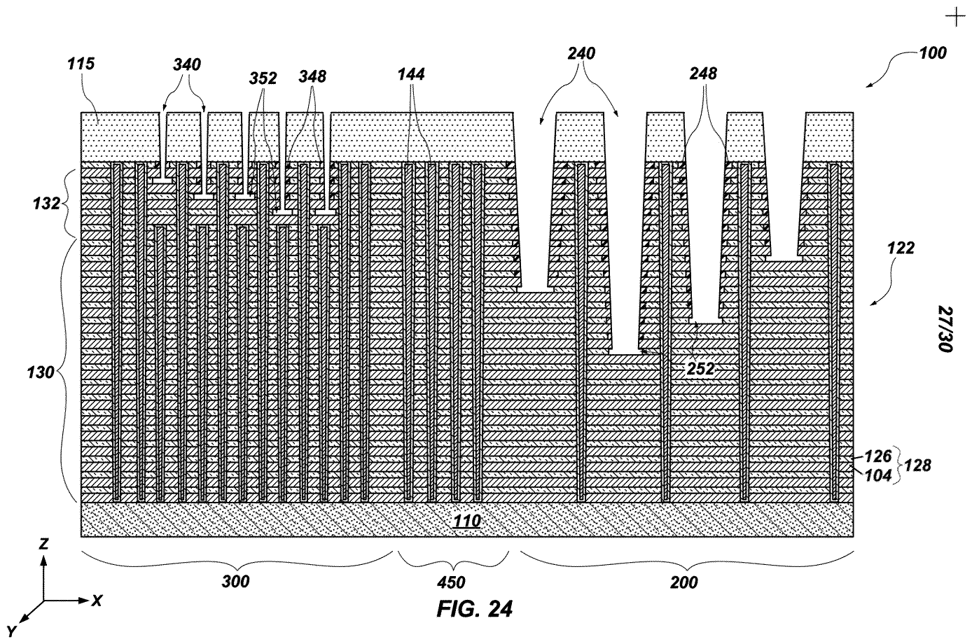

Referring next to FIG. 24, the contact sacrificial fill material in the sacrificially filled the WL contact structures 260 (FIGS. 23A and 23B) and the sacrificially filled the SGD contact structures 360 (FIGS. 23A and 23B) may be substantially removed to again form the WL contact openings 240 and the SGD contact openings 340, respectively. Further, the material of the carbon ion-implanted structures 250 (FIGS. 23A and 23B) may be removed to provide individual WL contact openings 240 with an expanded base 252 at the bottom thereof. In addition, the material of the additional carbon ion-implanted structures 350 (FIGS. 23A and 23B) may also be removed to provide individual SGD contact openings 340 with an expanded base 352 at the bottom thereof.

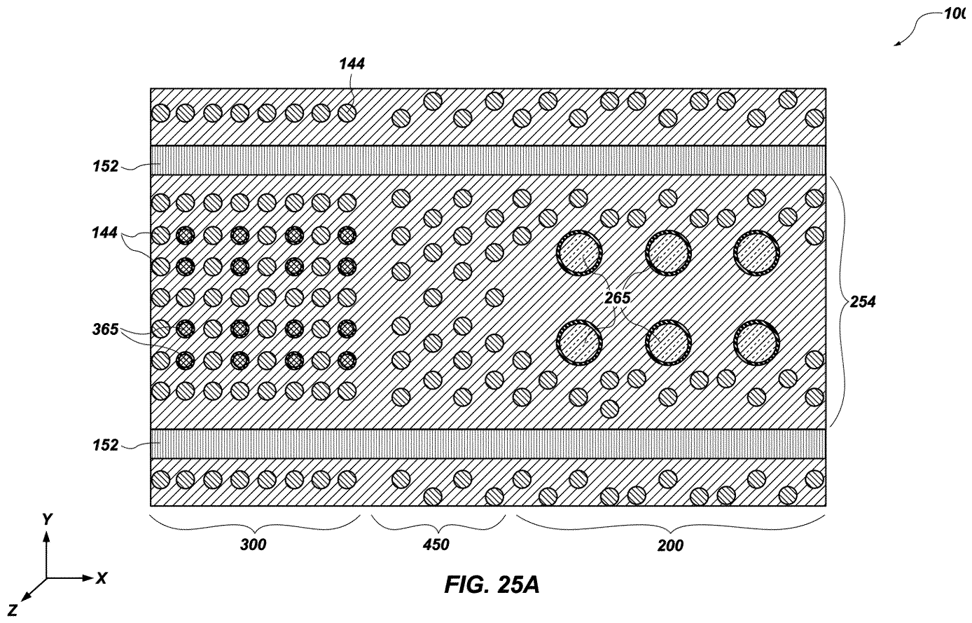

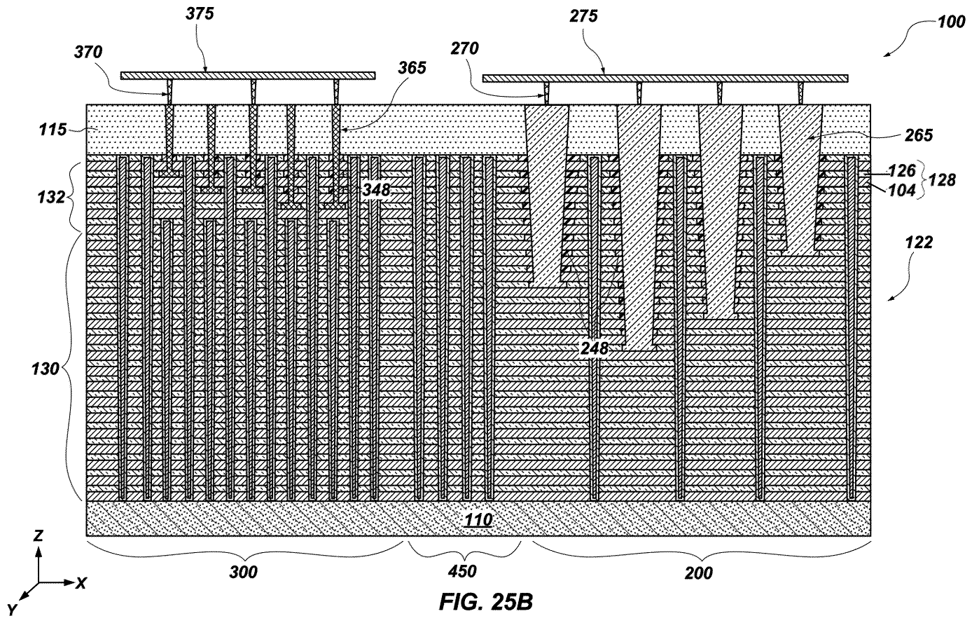

Referring collectively to FIGS. 25A and 25B, the WL contact openings 240 (FIG. 24) and the SGD contact openings 340 (FIG. 24) may be substantially filled with conductive material to form conductive contacts 265 and additional conductive contacts 365, respectively.

In the WL contact region 200, the conductive contacts 265 may individually be in contact (e.g., electrical contact) with the conductive material 126 of a respective one of the tiers 128 of the stack structure 122. For an individual conductive contact 265, the conductive contact 265 may contact the conductive material 126 of a tier 128 vertically overlapping (e.g., in the Z-direction) a base region (e.g., corresponding to the expanded base 252 in FIG. 24B) of the conductive contact 265. An individual conductive contact 265 may be isolated from the conductive material 126 of other tiers 128 of the stack structure 122 vertically above the tier 128 operatively associated therewith by the liner material 248 positioned horizontally between the conductive contact 265 and the conductive material 126 of the other tiers 128 of the stack structure 122.

In the extension/SGD contact region 300, the additional conductive contacts 365 may individually be in contact (e.g., electrical contact) with the conductive material 126 of a respective additional one of the tiers 128 of the stack structure 122. For an individual additional conductive contact 365, the additional conductive contact 365 may contact the conductive material 126 of an additional tier 128 vertically overlapping (e.g., in the Z-direction) a base region (e.g., corresponding to the expanded base 352 in FIG. 24B) of the additional conductive contact 365. An individual additional conductive contact 365 may be isolated from the conductive material 126 of further tiers 128 of the stack structure 122 vertically above the tier 128 operatively associated therewith by the liner material 248 positioned horizontally between the additional conductive contact 365 and the conductive material 126 of the further tiers 128 of the stack structure 122.

Still referring collectively to FIGS. 25A and 25B, after the replacement gate process, the replacement gate slots 151 (FIG. 23A) may be substantially filled with conductive material 126 to form the first dielectric-filled slot structures 152 previously described herein. The first dielectric-filled slot structures 152 may horizontally extend in parallel with one another in the X-direction and may horizontally alternate with the blocks 254 in the Y-direction.

As described previously in other embodiments (e.g., FIG. 9A), within a horizontal area of an individual block 254, one or more second dielectric-filled slot structures (e.g., dielectric-filled SGD openings) may be formed within the extension/SGD contact region 300 (and a memory array region) of the microelectronic device structure 100. For an individual block 254 of the stack structure 122, the second dielectric-filled slot structure may segment the conductive material 126 of at least some of the tiers 128 within the upper section 132 of the stack structure 122 into sub-blocks 256. For an individual block 254, portions of the conductive material 126 of individual tiers 128 within the upper section 132 of the stack structure 122 and within horizontal areas of the sub-blocks 256 of the block 254 may form the upper select gate structures (e.g., SGD structures) of the block 254 for upper select transistors (e.g., drain-side select transistors) formed within an array region of the block 254 horizontally neighboring the SGD contact region.

Thus, for an individual block 254 of the stack structure 122, the conductive material 126 of at least some of the tiers 128 within the lower section 130 of the stack structure 122 may be employed as access line structures (e.g., word line structures) of the block 254.

Interconnect structures 270 may be formed to vertically extend through the second dielectric fill material 117 to the conductive contacts 265. The interconnect structures 270 may individually be over (e.g., directly on) and in electrical contact with a respective one of the conductive contacts 265. In addition, additional conductive routing structures 275 may be formed over (e.g., directly on) and in electrical contact with the interconnect structures 270. The interconnect structures 270 may individually be coupled to and vertically intervene between a respective one of the conductive contacts 265 and a respective one of the additional conductive routing structures 275.

Additional interconnect structures 370 may be formed to vertically extend through the second dielectric fill material 117 to the additional conductive contacts 365. A material composition of the additional interconnect structures 370 may be substantially the same as a material composition of the interconnect structures 270, or a material composition of the additional interconnect structures 370 may be different from a material composition of the interconnect structures 270. The additional interconnect structures 370 may individually be over (e.g., directly on) and in electrical contact with a respective one of the additional conductive contacts 365. The conductive routing structures 375 may be formed over (e.g., directly on) and in electrical contact with the additional interconnect structures 370. The additional interconnect structures 370 may individually be coupled to and vertically intervene between a respective one of the additional conductive contacts 365 and a respective one of the conductive routing structures 375.

The structures, devices, system, and methods of the disclosure advantageously facilitate one or more of improved microelectronic device performance, reduced costs (e.g., manufacturing costs, material costs), increased miniaturization of components, and greater packaging density as compared to conventional structures, conventional devices, conventional systems, and conventional methods. The structures, devices, systems, and methods of the disclosure may also improve scalability, efficiency, and simplicity as compared to conventional structures, conventional devices, conventional systems, and conventional methods.

Thus, in accordance with embodiments of the disclosure, a microelectronic device includes a stack structure, an array region comprising strings of memory cells extending vertically through the stack structure, and an extension region horizontally neighboring the array region. The stack structure comprises levels of conductive material vertically alternating with levels of insulative material. Furthermore, the stack structure includes a lower section and an upper section vertically overlying the lower section. The extension region includes an array extension region abutting the array region, and a select gate drain (SGD) contact region at least partially horizontally overlapping the array extension region. The array extension region comprises pillar structures extending vertically through an entire vertical height of the stack structure. The SGD contact region comprises SGD contact structures individually extending vertically to one of the levels of conductive material within the upper section of the stack structure. The microelectronic device also includes a word line (WL) contact region horizontally neighboring the SGD contact region of the extension region. The WL contact region comprises WL contact structures individually in contact with another one of the levels of conductive material within the lower section of the stack structure and extending vertically through the entire vertical height of the stack structure.

Further, in accordance with embodiments of the disclosure, a method of forming a microelectronic device includes forming a preliminary stack structure comprising a vertically alternating sequence of sacrificial material and insulative material arranged in tiers. The preliminary stack structure includes a lower section and an upper section vertically overlying the lower section. Cell pillar structures are formed in an array region to extend vertically through an entire vertical height of the preliminary stack structure. Dummy pillar structures are formed in an array extension region horizontally abutting the array region. The dummy pillar structures extend vertically through the entire vertical height of the preliminary stack structure. Select gate drain (SGD) contact structures are formed in an SGD contact region at least partially horizontally overlapping the array extension region. The SGD contact structures extend vertically at least partially through the upper section of the preliminary stack structure. Word line (WL) contact structures are formed within a WL contact region horizontally neighboring the SGD contact region. The WL contact structures extend vertically at least partially through the lower section of the preliminary stack structure. The method also include replacing the sacrificial material in the tiers of the preliminary stack structure with conductive material to form a stack structure comprising a vertically alternating sequence of the conductive material and the insulative material.

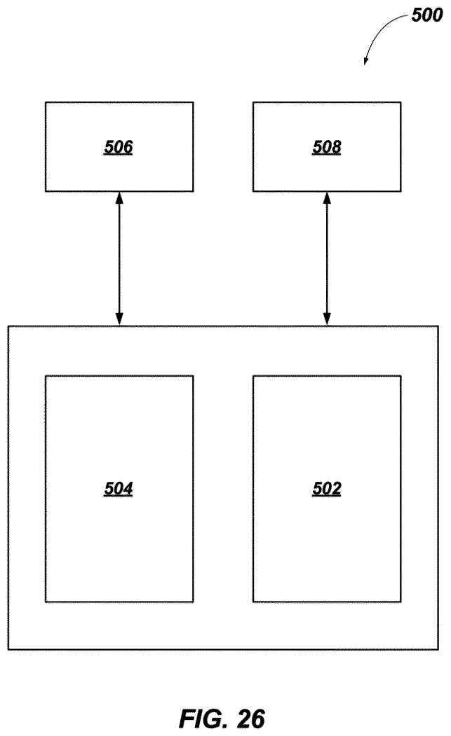

Microelectronic devices structures (e.g., the microelectronic device structures 100 of one or more of FIGS. 1, 9A, 9B, 14, 17, 25A or 25B) and microelectronic devices (e.g., memory devices including the microelectronic devices structures) in accordance with embodiments of the disclosure may be used in embodiments of electronic systems of the disclosure. For example, FIG. 26 is a block diagram of an electronic system 500 according to embodiments of disclosure. The electronic system 500 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 403 includes at least one memory device 502. The memory device 502 may include, for example, one or more microelectronic device structures (e.g., the microelectronic device structure 100 of one or more of FIGS. 1, 9A, 9B, 14, 17, 25A or 25B) previously described herein. The electronic system 500 may further include at least one electronic signal processor device 504 (often referred to as a “microprocessor”). The electronic signal processor device 504 may, optionally, include one or more microelectronic device structures (e.g., the microelectronic device structure 100 of one or more of FIGS. 1, 9A, 9B, 14, 17, 25A or 25B). While the memory device 502 and the electronic signal processor device 504 are depicted as two (2) separate devices in FIG. 26, in additional embodiments, a single (e.g., only one) memory/processor device having the functionalities of the memory device 502 and the electronic signal processor device 504 may be included in the electronic system 500. In such embodiments, the memory/processor device may include one or more microelectronic device structures (e.g., the microelectronic device structure 100 of one or more of FIGS. 1, 9A, 9B, 14, 17, 25A or 25B). The electronic system 500 may further include one or more input devices 506 for inputting information into the electronic system 500 by a user, such as, for example, a mouse or other pointing device, a keyboard, a touchpad, a button, or a control panel. The electronic system 500 may further include one or more output devices 508 for outputting information (e.g., visual or audio output) to a user such as, for example, a monitor, a display, a printer, an audio output jack, a speaker, etc. In some embodiments, the input device 506 and the output device 508 comprise a single touchscreen device that can be used both to input information to the electronic system 500 and to output visual information to a user. The input device 506 and the output device 508 may communicate electrically with one or more of the memory device 502 and the electronic signal processor device 504.

Thus, in accordance with embodiments of the disclosure, an electronic system includes an input device, an output device, a processor device operably coupled to the input device and the output device, and a memory device operably coupled to the processor device. The memory device includes a stack structure, cell pillar structures within an array region, support pillar structures in an array extension region horizontally abutting the array region, and select gate drain (SGD) contact structures in an SGD contact region at least partially horizontally overlapping the array extension region. The stack structure comprises a vertically alternating sequence of conductive structures and insulative structures arranged in tiers. The stack structure includes a lower section and an upper section vertically overlying the lower section. The cell pillar structures and the support pillar structures individually extend vertically through the stack structure. The select gate drain (SGD) contact structures extend vertically at least partially through the upper section of the stack structure, and are individually coupled to a respective one of the conductive structures within the upper section of the stack structure. The memory device also includes word line (WL) contact structures in a WL contact region horizontally neighboring the SGD contact region. The WL contact structures extend vertically at least partially through the lower section of the stack structure, and are individually coupled to an additional respective one of the conductive structures within the lower section of the stack structure.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure including levels of conductive material vertically alternating with levels of insulative material, the stack structure comprising a lower section and an upper section vertically overlying the lower section;
an array region comprising an strings of memory cells extending vertically through the stack structure;
an extension region horizontally neighboring the array region and comprising:
an array extension region abutting the array region and comprising pillar structures extending vertically through an entire vertical height of the stack structure; and
a select gate drain (SGD) contact region at least partially horizontally overlapping the array extension region, the SGD contact region comprising SGD contact structures individually extending vertically to one of the levels of conductive material within the upper section of the stack structure; and
a word line (WL) contact region horizontally neighboring the SGD contact region of the extension region, the WL contact region comprising WL contact structures individually in contact with another one of the levels of conductive material within the lower section of the stack structure and extending vertically through the entire vertical height of the stack structure.

2. The microelectronic device of claim 1, wherein at least 25 percent of the SGD contact region is horizontally overlapped by the array extension region.

3. The microelectronic device of claim 1, wherein the pillar structures of the array extension region are electrically isolated from at least one of source structure and digit line structures operatively associated with the strings of memory cells of the array region.

4. The microelectronic device of claim 1, wherein one or more of the SGD contact structures and the WL contact structures individually comprises a horizontally expanded base at a vertically lowermost portion thereof, the horizontally expanded base coupled to the conductive material of a respective one of the levels of conductive material of the stack structure.

5. The microelectronic device of claim 1, wherein at least one of the SGD contact region and the WL contact region is substantially free of any staircase structures within a horizontal area thereof and vertically overlapping the stack structure.

6. The microelectronic device of claim 1, wherein:
the SGD contact region comprises at least one SGD staircase structure in the upper section of the stack structure, and
the WL contact region comprises at least one WL staircase structure in the lower section of the stack structure.

7. The microelectronic device of claim 6, wherein:
the SGD contact structures have substantially a same vertical height as one another, and
the WL contact structures have substantially a same additional vertical height as one another.

8. The microelectronic device of claim 1, wherein the SGD contact structures extend vertically at least partially through the upper section of the stack structure and physically contact the conductive material of a respective one of the levels of conductive material within the upper section of the stack structure.

9. An electronic system, comprising:
an input device;
an output device;
a processor device operably coupled to the input device and the output device; and
a memory device operably coupled to the processor device, the memory device comprising:
a stack structure comprising a vertically alternating sequence of conductive structures and insulative structures arranged in tiers, the stack structure comprising a lower section and an upper section vertically overlying the lower section;
cell pillar structures within an array region and extending vertically through the stack structure;
support pillar structures in an array extension region and extending vertically through the stack structure, the array extension region horizontally abutting the array region;
select gate drain (SGD) contact structures in an SGD contact region at least partially horizontally overlapping the array extension region and extending vertically at least partially through the upper section of the stack structure, the SGD contact structures individually coupled to a respective one of the conductive structures within the upper section of the stack structure; and
word line (WL) contact structures in a WL contact region horizontally neighboring the SGD contact region and extending vertically at least partially through the lower section of the stack structure, the WL contact structures individually coupled to an additional respective one of the conductive structures within the lower section of the stack structure.

10. The electronic system of claim 9, wherein the WL contact structures respectively extend vertically through an entire vertical height of the stack structure.

11. The electronic system of claim 9, wherein:
the WL contact region further comprises at least one WL staircase structure comprising steps defined by edges of some of the tiers within the lower section of the stack structure, and
at least one of the WL contact structures individually comprises:
a first portion extending vertically through an entire height of the stack structure; and
a second portion continuous with outwardly horizontally projecting from the first portion, the second portion within a lateral area of one of the steps of the at least one WL staircase structure and coupled to one of the conductive structures of the stack structure partially defining the one of the steps.

12. The electronic system of claim 9, wherein:
the SGD contact region further comprises at least one SGD staircase structure comprising steps defined by edges of at least some of the tiers within the upper section of the stack structure, and
at least one of the SGD contact structure individually comprises:
a first portion extending vertically at least through a portion of the stack structure; and
a second portion continuous with outwardly horizontally projecting from the first portion, the second portion within a lateral area of one of the steps of the at least one SGD contact structure and coupled to one of the conductive structures of the stack structure partially defining the one of the steps.

13. The electronic system of claim 9, wherein at least one of the WL contact structures has a different vertical height than at least one other of the WL contact structures.

14. The electronic system of claim 9, wherein at least one of the SGD contact structures has a different vertical height than at least one other of the SGD contact structures.

15. The electronic system of claim 9, wherein the SGD contact structures individually have a smaller horizontal dimension than respective ones of the WL contact structures.

16. A method of forming a microelectronic device, comprising:
forming a preliminary stack structure comprising a vertically alternating sequence of sacrificial material and insulative material arranged in tiers, the preliminary stack structure comprising a lower section and an upper section vertically overlying the lower section;
forming cell pillar structures in an array region and extending vertically through an entire vertical height of the preliminary stack structure;
forming dummy pillar structures in an array extension region horizontally abutting the array region, the dummy pillar structures extending vertically through the entire vertical height of the preliminary stack structure;
forming select gate drain (SGD) contact structures in an SGD contact region at least partially horizontally overlapping the array extension region, the SGD contact structures extending vertically at least partially through the upper section of the preliminary stack structure;
forming word line (WL) contact structures within a WL contact region horizontally neighboring the SGD contact region and extending vertically at least partially through the lower section of the preliminary stack structure; and
replacing the sacrificial material in the tiers of the preliminary stack structure with conductive material to form a stack structure comprising a vertically alternating sequence of the conductive material and the insulative material.

17. The method of claim 16, wherein:
forming the SGD contact structures comprises forming SGD contact openings extending vertically at least partially through the upper section of the preliminary stack structure, at least one of the SGD contact openings terminating at a different tier of the upper section of the preliminary stack structure than other of the SGD contact openings, and
forming the WL contact structures comprises forming WL contact openings extending vertically at least partially through the lower section of the preliminary stack structure, at least one of the WL contact openings terminating at a different tier of the lower section of the preliminary stack structure than other of the WL contact openings.

18. The method of claim 16, wherein forming the SGD contact structures comprises:
forming SGD openings extending vertically at least partially through the upper section of the preliminary stack structure, the SGD openings individually partially defined sidewalls of some of the tiers within the upper section of the preliminary stack structure;
removing a portion of the sacrificial materials in the some of the tiers within the upper section of the preliminary stack structure proximate the SGD contact openings to create recesses in continuous with and horizontally projecting from the SGD contact openings;
substantially filling the recesses with additional insulative material; and
substantially filling the SGD openings with conductive material after substantially filling the recesses with the additional insulative material.

19. The method of claim 16, wherein forming the WL contact structures comprises:
forming at least one WL staircase structure within the lower section of the preliminary stack structure;
forming WL openings within a horizontal area of the at least one WL staircase structure and extending vertically at least partially through the lower section of the preliminary stack structure, the WL openings individually partially defined by at least some of the tiers within the lower section of the preliminary stack structure;
forming isolation structures horizontally interposed between respectively ones of WL openings and the sacrificial material of some of the tiers within the lower section of the preliminary stack structure;
forming lateral openings intersecting and continuous with the WL openings after forming isolation structures, the lateral openings individually vertically overlapping a respective one of the tiers within the lower section of the preliminary stack structure; and
substantially filling the WL openings and the lateral openings with conductive material.

20. The method of claim 16, wherein:
forming the WL contact structures comprises forming the WL contact structures within a horizontal area of WL staircase structure within the lower section of the preliminary stack structure, the WL staircase structure having steps defined by horizontal ends of at least some of the tiers within the lower section of the preliminary stack structure, and
forming the SGD contact structures comprises forming the SGD contact structures within a horizontal area of a SGD staircase structure within the upper section of the preliminary stack structure, the SGD staircase structure having additional steps defined by horizontal ends of at least some others of the tiers within the upper section of the preliminary stack structure.
